(19) United States
(12) Patent Application Publication
(10) Pub. No.: US 2024/0337799 A1
(43) Pub. Date: Oct. 10, 2024

(54) Co-Packaging Assembly and Method for Attaching Photonic Dies/Modules to Multi-Chip Active/Passive Substrate

(71) Applicant: Chipletz, Inc., Spicewood, TX (US)

(72) Inventors: Siddharth Ravichandran, Austin, TX (US); Michael Su, Austin, TX (US); Bryan Black, Spicewood, TX (US); Michael Alfano, Austin, TX (US)

(21) Appl. No.: 18/132,336

(22) Filed: Apr. 7, 2023

(51) Int. Cl. G02B 6/42

(52) U.S. Cl. CPC G02B 6/428; G02B 6/4238; G02B 6/4249; G02B 6/4269

(57) ABSTRACT

A method and apparatus are provided for manufacturing an integrated circuit package assembly which includes a multichip package substrate having active and/or passive circuit devices embedded in one or more substrate core layers, a plurality of encapsulated integrated circuit devices attached to the multichip package substrate, and an optical waveguide fiber connected to a photonic integrated circuit device that is located in either the multichip package substrate or the encapsulated plurality of integrated circuit devices, where the optical waveguide fiber is optically coupled to an exposed fiber coupling region of the photonic integrated circuit device.

### BACKGROUND OF THE INVENTION

### Field of the Invention

The present invention is directed in general to integrated circuit packages and methods of manufacturing same. In one aspect, the present invention relates to an integrated circuit package assembly photonic integrated circuit dies or modules attached together on a multi-chip active/passive substrate.

### Description of the Related Art

Due to the increasing cost and complexity for manufacturing integrated chips with higher density requirements that are running up against lithographic reticle limits, there are increasingly practical ceilings on how large an integrated circuit die can be manufactured. Another manufacturing challenge is the increasing difficulty in integrating disparate functional blocks using different transistors nodes and backend of line copper interconnect schemes on a single integrated circuit chip. In addition, increasing device density means that a single defect on a single IC chip can dramatically reduce the overall yield of the wafer used to manufacture the IC chip. One promising solution to improve yield and performance with reduced cost is to divide the overall circuit functionality among multiple smaller integrated circuits (or chiplets) having specialized functions. With this approach, the separate testing of the individual chiplets will result in smaller amount of silicon being rejected as defective than would be the case if the combined functionality were manufactured in a single chip, assuming a uniform fault distribution rate. However, this approach also requires extensive technical challenges with interconnecting multiple chiplets together, including longer signal routing paths with potentially higher losses, lower available bandwidth, higher power consumption and/or higher latency. Additional interconnect complications arise with different voltages, timing requirements, and protocols used by the chiplets, all of which make chiplets look like a less obvious approach.

One solution for addressing these challenges is to connect the chiplets into a single semiconductor package substrate, such as a common interposer or substrate, so that individually tested chiplets can be reassembled and packaged into a complete final SoC, thereby yielding a significantly larger number of functional SoCs. Such assemblies are referred to as System-in-Package (SiP) assemblies. An example of such a semiconductor package substrate is described in U.S. patent application Ser. No. 17/692,587 entitled “Semiconductor Package with Integrated Circuits” which was filed on Mar. 11, 2022, and which is incorporated herein by reference in its entirety as if fully set forth herein. The single semiconductor package substrate may be embodied as a silicon interposer or substrate having embedded passive or active components, such as a network of thin-film capacitors provided for vertical power delivery in a package where the capacitors are embedded in the package substrate core, thereby facilitating the connection of multiple ICs in a single package for critical AI workloads, immersive consumer experiences, and high-performance computing. While existing WLP approaches can provide interconnects between die pads with <50 μm pitch and solder balls with ˜0.5 mm pitch, there are processing costs and design constraints which constrain the ability of existing bumping technology solutions to achieve finer pitches while meeting the applicable performance, design, complexity and cost constraints for packing integrated circuit devices.

As will be appreciated, SiP assemblies have several advantages over a System-on-Chip (SoC), including the ability to combine many different IC chips (e.g., analog, digital, and radio frequency (RF) dice) in the same package, where each die is implemented using that domain's most appropriate technology process. Also, designers can employ a number of off-the-shelf dice coupled, perhaps, with a limited number of relatively small, internally-developed components. However, there are also challenges with combining disparate chips into a single packaged assembly since the individual die will often have different lateral and vertical dimensions, differing heat dissipation requirements, different pitch spacing requirements, etc. There are also interface-related challenges with integrating different types of circuits, such as optical and electrical circuits. As a result, the existing solutions for providing SiP assemblies are extremely difficult at a practical level.

### BRIEF DESCRIPTION OF THE DRAWINGS

The present invention may be understood, and its numerous objects, features and advantages obtained, when the following detailed description is considered in conjunction with the following drawings.

FIGS. 1a-d depict the evolution of integrated circuit package assemblies for integrating optics and switch ASIC dice.

FIG. 2 is a simplified cross-section view of an integrated circuit package assembly where edge coupling is used to connect a fiber to a photonics integrated circuit.

FIG. 3 is a simplified cross-section view of an integrated circuit package assembly where grating coupling is used to connect a fiber to a photonics integrated circuit.

FIG. 4 is a simplified cross-section view of an integrated circuit package assembly including a multi-chip substrate with embedded photonics integrated circuits connected to an attached ASIC die with built-in electronics integrated circuits in accordance with selected embodiments of the present disclosure

FIG. 5 is a simplified cross-section view of an integrated circuit package assembly including a multi-chip substrate with embedded photonics integrated circuits connected to attached discrete electronics integrated circuits in accordance with selected embodiments of the present disclosure.

FIG. 6 is a simplified cross-section view of an integrated circuit package assembly including a multi-chip substrate with an embedded face up photonics integrated circuit in accordance with selected embodiments of the present disclosure.

FIG. 7 is a simplified cross-section view of an integrated circuit package assembly including a multi-chip substrate with an embedded face up photonics integrated circuit placed in a blind cavity in accordance with selected embodiments of the present disclosure.

FIG. 8 is a sequence of simplified cross-section views to illustrate a blind cavity fabrication process for embedding a photonics integrated circuit in a multi-chip substrate in accordance with selected embodiments of the present disclosure.

FIG. 9 is a sequence of simplified cross-section views to illustrate a through cavity fabrication process for embedding a photonics integrated circuit in a multi-chip substrate in accordance with selected embodiments of the present disclosure.

FIG. 10 is a sequence of simplified cross-section views to illustrate a through cavity fabrication process for using a sacrificial protection layer when embedding a photonics integrated circuit in a multi-chip substrate in accordance with selected embodiments of the present disclosure.

FIG. 11 is a simplified cross-section view of an integrated circuit package assembly including a multi-chip substrate attached to a face down photonics integrated circuit and an ASIC circuit in accordance with selected embodiments of the present disclosure.

FIG. 12 illustrates simplified plan and perspective views of a face down photonics integrated circuit which overhangs an underlying attached multi-chip substrate in accordance with selected embodiments of the present disclosure.

FIG. 13 illustrates simplified plan and perspective views of a face down photonics integrated circuit which overhangs cutout regions from an underlying attached multi-chip substrate in accordance with selected embodiments of the present disclosure.

FIG. 14 is a simplified cross-section view of an integrated circuit package assembly including a multi-chip substrate attached to a face down photonics integrated circuit that is connected to an optical fiber using vertical backside coupling in accordance with selected die-level reconstruction embodiments of the present disclosure.

FIG. 15 is a simplified cross-section view of an integrated circuit package assembly including a multi-chip substrate attached to a face down photonics integrated circuit that is connected to an optical fiber using vertical backside coupling in accordance with selected substrate-level reconstruction embodiments of the present disclosure.

FIG. 16 illustrates a simplified flow chart showing a method for fabricating a package assembly wherein a photonics integrated circuit dice is co-packaged with a multi-chip package substrate in accordance with selected embodiments of the present disclosure.

### DETAILED DESCRIPTION

An integrated circuit package assembly and associated method of fabrication are disclosed for forming an integrated circuit package assembly with encapsulated photonics integrated circuit (IC) dice or chip modules embedded in, or attached to, a multi-chip package substrate with embedded active and/or passive circuit elements or devices. In embodiments where the photonics IC is embedded in the multi-chip package substrate, a waveguide fiber may be attached to a face-up embedded photonics IC using an edge coupling mechanism. When fabricating the embedded photonics IC in the multi-chip package substrate, a sacrificial protective layer may be formed over the fiber coupling region of the face-up embedded photonics IC to protect the fiber coupling region until the waveguide fiber is attached. In addition or in the alternative, the embedded photonics IC may be formed in the multi-chip package substrate to include electrical connections on both the top and bottom surfaces of the photonics IC, or only one of the surfaces. In other embodiments where the photonics IC is attached to the multi-chip package substrate, a waveguide fiber may be attached to a face-down photonics IC using an edge coupling or a grating coupling mechanism. When a face-down photonics IC is attached to the multi-chip package substrate, the active face-down surface of the photonics IC is positioned to extend past the side(s) of the multi-chip package substrate so that an edge coupling mechanism may be used to attach a waveguide fiber to an exposed fiber coupling region on the active face-down surface of the photonics IC. Alternatively, when a face-down photonics IC is attached to the multi-chip package substrate, a vertical backside or grating coupling mechanism may be used to attach a waveguide fiber to the backside surface of the face-down photonics IC after thinning the backside of the photonics IC.

In selected die-level reconstitution embodiments, one or more photonics ICs are attached as part of a plurality of multi-height integrated circuit dice or chip modules to a first temporary carrier. After encapsulating the multi-height integrated circuit dice or chip modules with a molding compound, a grinding process may be applied to expose the integrated circuit dice or chip modules at a flat heat dissipation surface. Subsequently, the encapsulated and grinded integrated circuit dice or chip modules are transferred to a second temporary carrier to form an assembly interface of interconnect conductor structures (e.g., micro-bumps, C4 bumps, solder balls, Cu—Cu joint, Nano sintered silver or Cu, etc.) on the integrated circuit dice or chip modules. Subsequently, the integrated circuit dice or chip modules are transferred to a dicing tape for singulation into individual modules. Each individual module may be attached to a multi-chip package substrate with embedded active and/or passive circuit elements, after which a heat sink lid/cover can be formed with one or more thermal conductive layers to contact at least the exposed integrated circuit dice/chip modules. By applying a selective etch process to remove the heat sink lid/cover, a fiber coupling region on the backside surface of the photonics IC may be exposed and thinned so that a vertical backside or grating coupling mechanism may be used to attach a waveguide fiber to the fiber coupling region of the photonics IC.

In selected substrate-level reconstitution embodiments, a panel of package substrates with embedded active and/or passive circuit elements are attached to a temporary carrier. Subsequently, a plurality of multi-height integrated circuit dice or chip modules (including one or more photonics ICs) with an assembly interface of interconnect conductor structures are attached to each of the package substrates. After encapsulating the multi-height integrated circuit dice or chip modules with a molding compound, a grinding process may be applied to expose the integrated circuit dice or chip modules at a flat heat dissipation surface, and then the encapsulated and grinded panel of integrated circuit dice or chip modules are transferred to a dicing tape for singulation into individual modules which may be attached to a heat sink lid/cover with one or more thermal conductive layers to contact at least the exposed integrated circuit dice/chip modules. By applying a selective etch process to remove the heat sink lid/cover, the backside surfaces of the photonics ICs may be exposed and thinned, followed by forming a vertical backside or grating coupling mechanism to attach a waveguide fiber to the fiber coupling region of the thinned photonics IC. Subsequently, the encapsulated panel/package substrate(s) may be singulated into individual integrated circuit package assemblies.

Various illustrative embodiments will now be described in detail with reference to the accompanying figures. While various details are set forth in the following description, it will be appreciated that the present invention may be practiced without these specific details, and that numerous implementation-specific decisions may be made to the invention described herein to achieve the device designer's specific goals, such as compliance with process technology or design-related constraints, which will vary from one implementation to another. While such a development effort might be complex and time-consuming, it would nevertheless be a routine undertaking for those of ordinary skill in the art having the benefit of this disclosure. For example, selected aspects are depicted with reference to simplified cross sectional drawings of a package assembly without including every device feature or geometry in order to avoid limiting or obscuring the present invention. It is also noted that, throughout this detailed description, certain materials will be formed and removed to fabricate the package assembly structure. Where the specific procedures for forming or removing such materials are not detailed below, conventional techniques to one skilled in the art for growing, depositing, removing or otherwise forming such layers at appropriate thicknesses shall be intended. Such details are well known and not considered necessary to teach one skilled in the art of how to make or use the present invention.

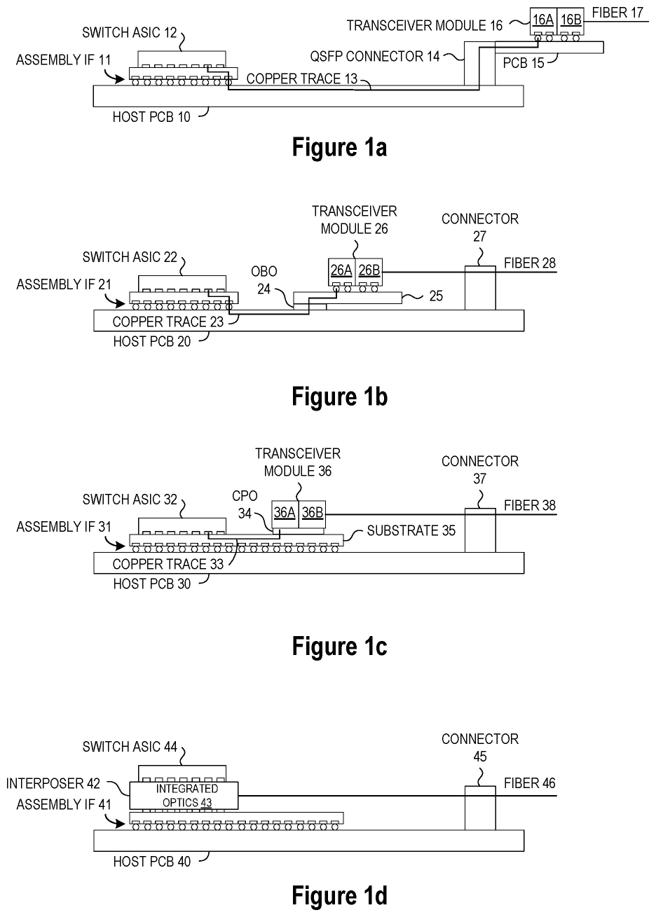

To provide contextual background information for the present disclosure, reference is now made to FIGS. 1a-d which depict the evolution of optics and ASIC integration over time, where an ASIC die provides computational functionality in the electrical domain and where an optics die converts signals from electrical to optical domains and vice versa. As depicted in these figures, there is a general trend in the space of networking and high-performance computing to bring the optics transceiver functionality closer to the ASIC computing functionality. This trend is driven by the need for system performance in terms of increasing bandwidth density demands, cost per capacity, and energy efficiency. However, system performance increases are limited by the electrical link in the form of long copper traces between the ASIC die and optical die. While designs have been proposed to make this electrical link shorter, there are design challenges with completely eliminating the electrical link that have not been solved with existing solutions.

To illustrate the evolutionary trend of integrated circuit package assemblies for integrating optics and ASIC circuit functionality, reference is now made to FIG. 1a which depicts a pluggable optics configuration for connecting a switch ASIC die 12 (or other integrated circuit, such as an GPU, CPU, etc.) to an optical transceiver module 16 using a faceplate-mounting approach. As depicted, the switch IC die 12 is connected over an assembly interface 11 to a host printed circuit board (PCB) 10. In addition, the optical transceiver module 16 is connected over an assembly interface to the printed circuit board (PCB) 15. When providing a photonic transceiver function, the optical transceiver module 16 may be connected to an optical fiber 17 to send and receive optical domain signals, and may also be connected to the switch ASIC 12 to send and receive electrical domain signals. In addition, the optical transceiver module 16 may include an electrical block 16A, a photonic block 16B, and a laser unit (not shown). Depending on the technology, specification, and cost of the system, these functions may be built as a single IC or might be broken up as multiple ICs. For example, the photonics functions may be built on a photonics-compatible silicon process technology, such as Radio Frequency Silicon On Insulator (RF-SOI), and may be referred to as Silicon Photonics IC (SiPh or simply Photonics IC or PIC). In addition, the electronic functions may be built on a 14 nm or 5 nm CMOS process (Electronics IC or EIC). In addition, the laser could be completely external to the optical transceiver module 16. The EIC 16A generally performs the role of electrical front-end which bi-directionally communicates with the switch ASIC 12, and may also include test and control signals for the PIC 16B. The EIC 16A is connected to the PIC 16B through an electrical interface, such as die wiring (if EIC 16A and PIC 16B are on the same die) or by means of package-level connections, such as bumps wiring (if the EIC 16A and PIC 16B are different dies). The PIC 16B may include photonic waveguides, interferometers, resonators, filters, couplers, etc. that are built using suitable semiconductor materials and processes. In this way, the PIC 16B modulates/demodulates the optical signals to/from an optical fiber/fiber array 17 and provides an optical/electrical interface for communicating electrical data signals to/from the EIC 16A. In FIG. 1a, the optical transceiver module 16 is connected to communicate with the switch ASIC 12 using a conductive wire or copper trace 13 which extends from the optical transceiver module 16 and through the PCB 15, Quad Small Form-factor Pluggable (connector 14, host PCB 10, and assembly interface 11.

To further illustrate the trend in integrating optics and ASIC circuit functionality, reference is now made to FIG. 1b which depicts an on-board optics configuration for connecting a switch ASIC die 22 to an optical transceiver module 26 using a mid-board mounting approach where the switch IC die 22 is connected over an assembly interface 21 to a host PCB 20, and where the optical transceiver module 26 is connected over an assembly interface 25 and on-board optics (OBO) connector 24 to the host PCB 20. In this configuration, the optical transceiver module 26 includes a PIC 26B which is coupled over a connector 27 to the optical fiber 28 to send and receive optical domain signals. In addition, the optical transceiver module 26 includes an EIC 26A which is electrically connected to the switch ASIC 22 to send and receive electrical domain signals. However, the length of the electrical connection is much shorter since the electrical connection path from the optical transceiver module 26 uses a conductive wire or copper trace 23 which extends from the optical transceiver module 26 and through the assembly interface 25, OBO connector 24, host PCB 20, and assembly interface 21.

To further illustrate the trend in integrating optics and ASIC circuit functionality, reference is now made to FIG. 1c which depicts a 2.5D integration on a common substrate configuration for connecting a switch ASIC die 32 to an optical transceiver module or engine 36 using a co-packaged optics (CPO) approach where the switch IC die 32 and optical transceiver module 36 are connected on a common substrate 35 which, in turn, is connected over an assembly interface 31 to a host PCB 30. In this configuration, the optical transceiver module 36 includes a PIC 36B which is coupled over a connector 37 to the optical fiber 38 to send and receive optical domain signals. In addition, the optical transceiver module 36 includes an EIC 36A which is electrically connected to the switch ASIC 32 over the copper trace 33 formed in the common substrate 35 to send and receive electrical domain signals. As depicted, the length of the electrical connection 33 is much shorter since the electrical connection path from the optical transceiver module 36 uses a conductive wire or copper trace 33 which extends from the optical transceiver module 36 and through the CPO connector 34 and common substrate 35.

To further illustrate the trend in integrating optics and ASIC circuit functionality, reference is now made to FIG. 1d which depicts a fully 3D-integrated configuration for connecting a switch ASIC die 44 to an optical transceiver engine 43 that is integrated into an active photonic interposer 42. In this configuration, the interposer 42 may be implemented as an active photonic interposer with a fully integrated optics 43 which is coupled over the connector 45 to the optical fiber 46 to send and receive optical domain signals. In addition, the interposer 42 connects the fully integrated optics 43 to the switch ASIC 44 which implements the EIC functionality. As a result, the electrical connection between the fully integrated optics 43 and EIC functionality is greatly reduced. While co-packaged optics have been proposed, the industry has not yet achieved full alignment on CPO, and there are many design challenges to address that have not been solved which relate not only to the design of co-packaged optics circuitry. In addition, there are design challenges with connecting optical fibers to photonics integrated circuits. Generally, there are two main approaches of fiber-to-chip coupling, namely vertical coupling (or off-plane coupling) and edge coupling (or in-plane coupling) which differ in terms of the relative position of fiber and the photonic chip. For vertical coupling, grating couplers are mostly used, and fiber is placed vertically above the PIC or slightly slanted at a certain degree to ensure high coupling efficiency. Grating couplers have some major advantages including compact size, wafer-level testing capability, and flexible coupling position, but there are also some drawbacks, such as a relatively low coupling efficiency, narrow bandwidth, and high wavelength sensitivity. As for edge couplers where the optical fiber is typically placed at the wafer facet and aligned with the Si waveguides horizontally, it is common to form V-grooves in the side edge of the photonics IC, thereby providing an opening which is used to align the coupling or connection of the optical fiber to the end-fire waveguide(s) on a photonics IC. While edge couplers can achieve rather high coupling efficiency, broad bandwidth, and polarization independence, they also have some limitations, including relatively a larger footprint than grating couplers, fixed coupling position, and more strict requirements of the coupling facet.

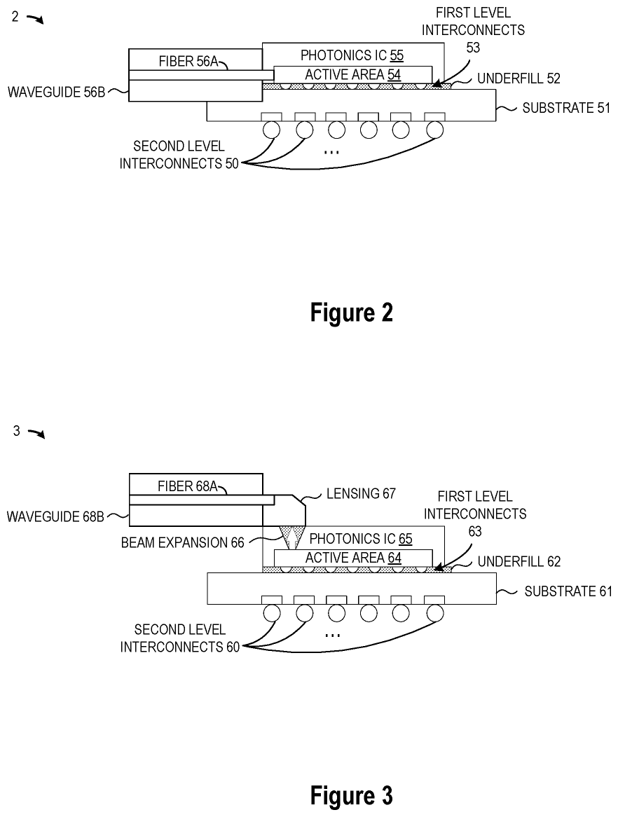

To illustrate some of the design challenges with connecting optical fibers to photonics integrated circuits, reference is now made to FIG. 2 which depicts a simplified cross-section view 2 of an integrated circuit package assembly 51-55 where edge coupling is used to connect an optical waveguide fiber 56 to the active area 54 of a photonics integrated circuit 55. As depicted, the photonics IC 55 has an active area 54 formed on a bottom surface of the photonics IC 55. At the bottom surface, first level interconnects 53 are formed to connect the photonics IC 55 to a first surface of the underlying substrate 51, and are filled with an underfill layer or material 52. On a second, opposed surface of substrate 51, second level interconnects 50 are formed for electrical connection to a PCB or other external circuitry (not shown). At a first side edge of the photonics IC 55, the optical fiber 56A and waveguide 56B are positioned for edge coupling to the active area 54 of the photonics IC 55. As understood by those skilled in the art, edge coupling refers to an approach where one or more optical fibers are butted to the edge of end-fire waveguide(s) on a photonics IC. Because edge coupling is sensitive to alignment between the optical fiber 56A and the active area 54, V-grooves may be formed in the side edge of the photonics IC to provide an opening which is used to align the coupling or connection of the optical fiber to the end-fire waveguide(s) on a photonics IC. However, as the number of optical fibers increases to provide more bandwidth, the size of the V-groove dimensions and fiber diameters start to shrink, thereby necessitating costly active fiber alignment techniques which require that the fiber coupling region of each photonics IC is exposed for fiber pick and place handlers to look at and actively align the optical fiber.

To illustrate other design challenges with connecting optical fibers to photonics integrated circuits, reference is now made to FIG. 3 which depicts a simplified cross-section view 3 of an integrated circuit package assembly 60-65 where grating coupling is used to connect an optical waveguide fiber 68 to the active area 64 of a photonics integrated circuit 65. As depicted, the active area 64 on the bottom of the photonics IC 65 is connected over first level interconnects 63 to a first surface of the underlying substrate 61, where an underfill layer or material 62 surrounds the first level interconnects 63 between the photonics IC 65 and substrate 61. On a second, opposed surface of substrate 51, second level interconnects 50 are formed for electrical connection to a PCB or other external circuitry (not shown). On a fiber coupling region formed on the top surface of the photonics IC 55, the optical fiber 68A and waveguide 68B are positioned for vertical or grating coupling to the active area 64 of the photonics IC 65. As understood by those skilled in the art, grating coupling describes a coupling mechanism where the light is coupled across the vertical thickness of the photonics IC 65, thereby incurring beam expansion 66 effects where the light is partially diffused by the body of the photonics IC. As a result of this diffusion effect, grating couplers have inefficiencies that require a complex mirror and lensing structure 67 to obtain reasonable levels of optical transmission efficiency. While grating couplers are less sensitive to alignment issues than edge couplers, they are more sensitive the distance between the active area 64 and the lensing 67. While one solution to the diffusion problem would be to reduce the working distance between the active area 64 and the lensing 67, such as by applying a localized thinning of the photonics IC 65, but this makes it difficult to handle the photonics IC 65 in assembly, and also creates difficulties with attaching thermal heat/lid dissipation structures to the photonics IC 65 during subsequent processing.

As described hereinabove, the trend with optics and ASIC circuit integration is to bring the photonics functionality very close to the ASIC computational functionality with a co-packaged optics (CPO) integration scheme, but the use of silicon photonics (SiPh) die fabrication techniques and fiber coupling processes must be compatible with state-of-the-art advanced packaging flows and assembly techniques, and there are a number of challenges with implementing co-packaged optics with SiPh die fabrication techniques.

For example, existing photonic ICs are typically mounted face up (active side up) with the “face-up” pads connected to the underlying package substrate/board with wire bonds, thereby allowing an exposed fiber coupling region on the “face-up” surface to use a conventional fiber attach process. However, advanced packaging options now use flip-chip assembly processes where the die is “face down” so that connections to the underlying package substrate/board are made through solder bumps (e.g., C4 bumps), micro-bumps (solder with copper pillar), or the like. While such flip-chip connections enable more connections in comparison to wire-bonding, it is difficult to attach optical fibers to the “face-down” surface of the photonics IC. To enable edge coupling of optical fibers to a face-down photonics IC, a package assembly may position the photonics IC to extend past or over-hand the underlying substrate, thereby exposing a fiber attach region on the exposed underside of the photonics IC. However, there are difficulties with the “over-hang” approach, including underfill bleed out and incompatibility with state of the art advanced packaging approaches. For example, advanced packaging techniques require high density, fine pitch wiring between two or more dies and die stacks through a silicon interposer or wafer-level fanout (both wafer-level processes). In addition or in the alternative, cutout regions may need to be etched into the underlying substrates to accommodate optical waveguide fibers that are too thick to fit under the overhanging photonics IC. Accordingly, it can be seen that advanced packaging techniques are not amenable with forming overhanging dies or cutouts in them to support edge coupling fiber optic connections.

The use of over-hanging “face down” photonic ICs also faces compatibility challenges with state-of-the-art thermal solutions in multi-die packages (e.g., 2.5D silicon interposer, multi-die fanout packages, bridge, etc.) which require a flat top or backside of the multiple dice for attaching a heat spreader lid or cover. In particular, when co-packaging dissimilar dies or die-stacks, their heights may not be the same, resulting in a non-flat backside. Existing solutions can solve this by forming a molding cover and then back-grinding the molding compound to achieve a uniform height for all of the dice. However, the use of back-grinding is not workable in the case of over-hanging photonic ICs since they cannot withstand the mechanical grinding stress.

Yet another compatibility challenge with state-of-the-art thermal solutions is the reflow compatibility of attaching an optical waveguide fiber in the midst of the optical co-packaging process. For example, optical waveguide fibers are typically attached to photonic ICs using fiber optic ferrules, tacking adhesives, glob tops, etc. Unfortunately, these materials do not withstand reflow temperatures (>240 C) which are often used optical co-packaging processes. There are also issues caused by dangling fibers through the remainder of the module and system integration process. While there have been some advances made so that ferrules and glob tops are resistant to higher temperatures, it is difficult to make fiber tack adhesives that are compatible with high temperatures since getting better optical properties and temperature resistance properties of polymers are inversely related to each other.

To provide an improved understanding of the foregoing challenges of connecting optical fibers to photonic ICs, there is disclosed herein an integrated circuit package assembly and associated method of fabricating encapsulated photonics integrated circuit (IC) dice or chip modules to enable a post-reflow optical waveguide fiber attachment to a fiber coupling region on the photonics IC that can exposed while still tightly integrated with a co-packaged ASIC die. To this end, the disclosed integrated circuit package assembly eliminates the need for an interposer or fanout module by integrating or attaching one or more photonic ICs with a multi-chip package substrate with integrated fine-pitch wiring layers and embedded passive and active components in the substrate core, where each photonic IC includes an exposed fiber coupling region that can be connected to an optical fiber using any suitable fiber attach process and materials.

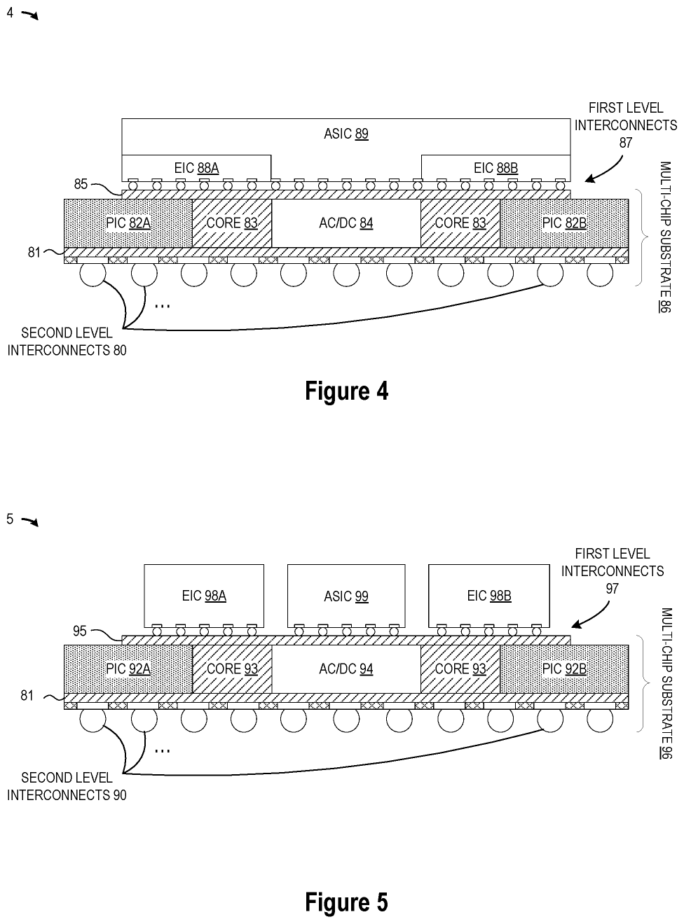

For an improved understanding of selected embodiments of the present disclosure, reference is now made to FIG. 4 which shows a simplified cross-section view of an integrated circuit package assembly 4 including a multi-chip substrate 86 with embedded photonics integrated circuits 82A, 82B connected to an attached ASIC die 89 with built-in electronics integrated circuits 88A, 88B. As depicted, the integrated circuit package assembly 4 is implemented as a flip chip package wherein the ASIC die/chip module 89 is connected to the multi-chip substrate 86 using the first level interconnects 87 (e.g., solder bumps or micro-bump conductors), and where the multi-chip substrate 86 is externally connected using the second level interconnects 80 (e.g., solder balls or bumps). As will be appreciated, the first and second level interconnects 87, 80 are not restricted to solder balls/bumps, and can include land grid array (LGA), ball grid array (BGA), etc.

In the ASIC die/chip module 89, there are built-in electronic integrated circuits 88A, 88B shown as being positioned on peripheral sides of the ASIC die/chip module 89 with face-down active layers. In the multi-chip substrate 86, there is one or more face-up photonics ICs 82A, 82B embedded in the substrate core 83, alone or in combination with other active/passive (AC/DC) components 84. In addition, the embedded photonic ICs 82, core 83, and AC/DC chip/modules 84 are sandwiched between a first or upper redistribution line (RDL) stack 85 and a second or lower RDL stack 81. (Though shown in simplified form as a single layer, it will be appreciated that each stack 81, 85 is a combination of conductive elements or layers formed in one or more first insulator layers). As formed, the face-up photonic ICs 82A, 82B are positioned in overlapping alignment with the electronic ICs 88A, 88B. In addition, the first or upper RDL stack 85 is selectively formed or patterned to expose a fiber coupling region on top of the photonic ICs 82A, 82B and to leave a remnant first or upper RDL stack 85 for connecting the photonic ICs 82A, 82B to the electrical ICs 88A, 88B. In this arrangement, the EICs 88 are positioned in close proximity to the PICs 82 and thus tightly connected with very short vertical RDL and via connections. In addition, the exposed fiber coupling regions on top of the photonic ICs 82A, 82B are positioned to enable direct attachment to optical waveguide fibers (not shown) without having any overhang of the photonic ICs 82 and without requiring any cutout or etching of the multi-chip substrate 86. As a result, any suitable fiber attach technique can be employed to attach optical waveguide fibers to the exposed fiber coupling regions on top of the face-up photonic ICs 82A, 82B, and this attachment can be performed after the board-attach process, thereby eliminating problems caused when the optical fiber attach materials are not reflow-compatible.

For an improved understanding of selected embodiments of the present disclosure, reference is now made to FIG. 5 which shows a simplified cross-section view of an integrated circuit package assembly 5 including a multi-chip substrate 96 with embedded photonics integrated circuits 92 connected to a plurality of attached dice, including discrete electronics integrated circuits 98A, 98B and an ASIC 99. Implemented as a flip chip package, the integrated circuit package assembly 5 includes first level interconnects 97 connecting the discrete chips 98-99 to the multi-chip substrate 96, and also includes second level interconnects 90 connecting the multi-chip substrate 96 to external circuits, such as a printed circuit board (not shown). As depicted, the electronic integrated circuits 98A, 98B are positioned and attached on peripheral sides of the ASIC 99 with face-down active layers for overlapping alignment with the embedded face-up photonics ICs 92A, 92B in the multi-chip substrate 96. In addition, the embedded photonic ICs 92, core 93, and AC/DC chip/modules 94 are sandwiched between a first or upper RDL stack 95 and a second or lower RDL stack 91. In addition, the first or upper RDL stack 95 is selectively formed or patterned to expose a fiber coupling region on top of the photonic ICs 92 and to leave a remnant first or upper RDL stack 95 for connecting the photonic ICs 92 to the electrical ICs 98. In this arrangement, the EICs 98 are positioned in close proximity to the PICs 92 and thus tightly connected with very short vertical RDL and via connections. In addition, the exposed fiber coupling regions on top of the photonic ICs 92 are positioned to enable direct attachment to optical waveguide fibers (not shown) without having any overhang of the photonic ICs 92 and without requiring any cutout or etching of the multi-chip substrate 96. As a result, any suitable fiber attach technique can be employed to attach optical waveguide fibers to the exposed fiber coupling regions on top of the face-up photonic ICs 92, and this attachment can be performed after the board-attach process, thereby eliminating problems caused when the optical fiber attach materials are not reflow-compatible.

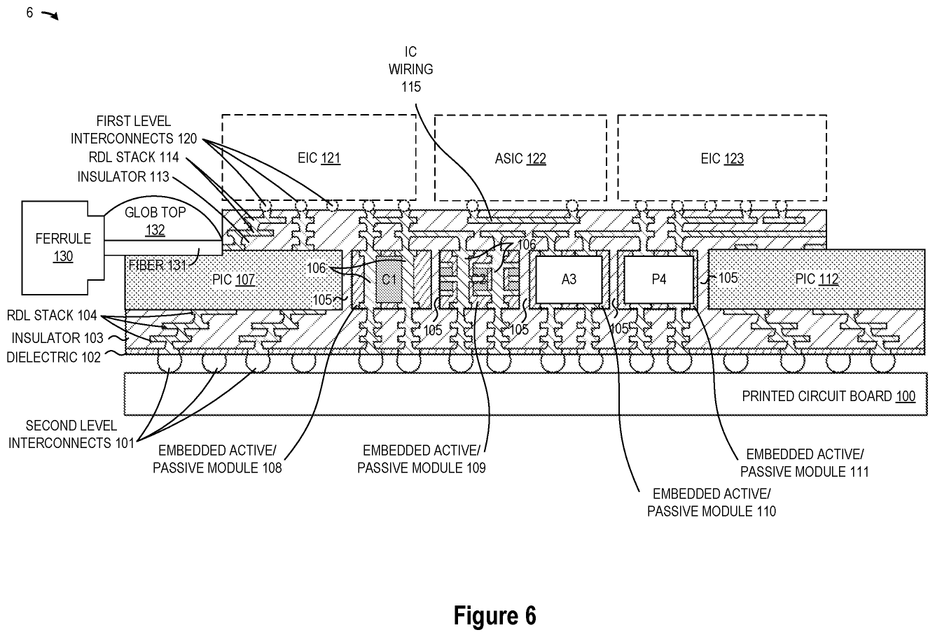

For an improved understanding of selected embodiments of the present disclosure, reference is now made to FIG. 6 which depicts a cross-sectional view of an integrated circuit package assembly 6 wherein a plurality of die/chip modules 121-123 are affixed to a multi-chip package substrate 101-115 with embedded active and/or passive modules 108-111 and face-up photonics ICs 107, 112. As depicted, the integrated circuit package assembly 6 is implemented as a flip chip package wherein the die/chip modules 121-123 are connected to one another and to the printed circuit board 100 using defined conductive elements and the embedded active and/or passive modules in the multi-chip package substrate 101-115. In particular, the flip chip package assembly has a plurality of surface-attachable die or module devices 121-123, including discrete electronics integrated circuits 121, 123 and an ASIC 122. The depicted die/module devices 121-123 are attached to a first or top surface of the multi-chip package substrate 101-115 using a set of first level interconnects 120, such as solder bumps or micro-bump conductors. In similar fashion, a second or bottom surface of the multi-chip package substrate 101-115 is attached to the printed circuit board 100 using a set of second level interconnects 101, such as a plurality of solder balls or bumps.

To support and enable electrical connection between the die/chip modules 121-123 and the printed circuit board 100, the multi-chip package substrate 101-115 includes a substrate core that is formed with an insulating material (e.g., plastic and/or fiberglass) that is sandwiched between first and second redistribution line (RDL) stacks 102-104, 113-115. In the substrate core, one or more embedded active and/or passive modules 107-112 are formed. As illustrated, a plurality of embedded active and/or passive modules 107-112 may be separately formed in separate cavities of the substrate core to be isolated from one another by an intervening insulation layer 105, but in other embodiments, the embedded active and/or passive modules 107-112 may be formed in a single continuous cavity of the substrate core.

As depicted, the embedded active and/or passive modules 107-112 may include a variety of different circuit components that may take any suitable form, shape, size, thickness, or structure. In addition, one or more of the embedded active and/or passive modules 107-112 can be positioned in alignment with an outline or power domain of an IC die/chip module 121-123. For example, there may be design and performance benefits from aligning the position of one or more surface attachable devices (e.g., die/module 122) so that has a “shadow” within which the underlying embedded circuit components (e.g., capacitor C2 or active circuit component A3) are located. As a result, each embedded circuit component can follow the physical layout or profile of each domain/functional block of a single surface attachable device. While one or more embedded circuit components can be positioned to service a single surface attachable device under its shadow, the connections between the capacitors and surface attachable devices through the package RDL stack 113-115 can also allow an embedded circuit component to service multiple surface attachable devices.

By way of providing an example embedded circuit component, one or more “face-up” photonic IC dice 107, 112 may be embedded in the multi-chip substrate. In addition, the multi-chip substrate may include an embedded vertical planar capacitor C1 at embedded module 108 which includes a pair of capacitor plates formed from the conductive via structures 106 which are separated by a capacitor dielectric. In addition or in the alternative, the multi-chip substrate may include a second embedded vertical multi-layer capacitor C2 at embedded module 109 which is constructed with sandwiched capacitor plate layers including interleaved conductive fingers which are attached to the conductive via structures 106 and separated by a capacitor dielectric. Thus, any suitable capacitor can be embedded, including a multi-layer ceramic capacitor (MLCC), thin-film based (Al, Ta, etc.), polymer-cap, etc., and can include a combination of different types of capacitors for different voltages (1.2 V, 5V, 100V depending on the capacitor), frequencies, and densities. To provide another example of an embedded circuit component, the multi-chip substrate may include an active circuit component A3 at embedded module 110 for implementing a specified power, RF, digital and/or photonic functionality, such as filtering power noise, converting and/or regulating regulate voltage, assisting with die-to-die communication, etc. And to provide another example of an embedded circuit component, the multi-chip substrate may include a passive circuit component P4 at embedded module 111, which may include any type of passive component, such as a capacitor, resistor, inductor, etc.

As illustrated, one or more of the embedded active and/or passive modules 107-112 may be connected on both top and bottom surfaces to the first and second RDL stacks 102-104, 113-115 so that electrical signal and/or thermal conduction passes between the first and second level interconnects 101, 120. However, it will be appreciated that one or more of the photonic ICs may be connected on only a single side to an RDL stack, such as shown with the photonic IC 107 which is connected only through the first RDL stack 113-115 to the electronic IC 121.

By forming at least a portion of the multi-chip substrate with embedded capacitor(s), at least some of the vertical connections in the first and second RDL stacks 102-104, 113-115 can connect the capacitor(s) to the external circuitry on the PCB 100 and at least one of the attachable IC die/chip modules 121-123 for filtering AC noise from the DC power. Moreover, embedding or forming the multi-chip substrate with the capacitor(s) and providing vertical delivery of DC power through the capacitor(s) avoids RC signal delays and poor device density resulting from the use of decoupling capacitors having terminals on left and right sides for lateral power delivery and signal routing through the capacitor or placement of the capacitor on the surface of the package.

The multi-chip substrate also includes one or more defined conductive signal or power via elements 106 to provide electrical and/or thermal conductive paths through the multi-chip substrate and the embedded active and/or passive modules 107-112. The conductive signal or power via elements 106 may be formed as conductive via structures which extend through the multi-chip substrate and which have top and bottom terminal landing pads. At least one of the conductive via elements 106 is provided for vertically passing DC power from the external circuitry 100 to one or more of the die/chip modules 121-123, either directly or through one of the embedded active/passive modules 107-112. In selected embodiments, each conductive signal or power via element 106 may be embodied as a plated-through hole (PTHs).

On a first or top surface of the multi-chip substrate, the first RDL stack 113-115 may include conductive elements 114 formed in one or more insulator layer(s) 113 to connect the set of first level interconnects 120 to the defined conductive signal or power via elements 106 and embedded active and/or passive modules 107-112. When used for interconnecting to the IC die/chip modules 121-123, the first RDL stack 113-115 may have fine-pitch routing layers. In addition, one or more fine-pitch IC wiring lines 115 can also be provided in the first RDL stack for signaling between the die/chip modules 121-123. And on a second or bottom surface of the multi-chip substrate, the second RDL stack 102-104 may include conductive elements 104 formed in one or more second insulator layer(s) 103 to connect the set of second level interconnects 101 to the defined conductive signal or power via elements 106 and embedded active and/or passive modules 107-112. When used for interconnecting to the second level interconnects 101, the second RDL stack 102-104 may have a few course-pitch routing layers for power or I/O connections to the PCB 100. As a result of the configurations of the first and second RDL stacks 102-104, 113-115, terminal metals can be extremely close to each other, allowing small pitch first level interconnect micro-bumps 120 (e.g., 80 micron pitch) to vertically align with second level interconnect solder balls 101 without laterally routing of DC power lines through the RDL stacks 102-104, 113-115.

As depicted, the die/module devices 121-123 can be any suitable integrated circuit devices, integrated passive devices, microelectromechanical systems (MEMS). In selected embodiments, the die/module devices 121-123 include discrete electronics integrated circuits 121, 123 and a switch ASIC 122 which are attached “face down” to the multi-chip package substrate 101-115. By positioning and attaching the electronic integrated circuits 121, 123 on peripheral sides of the ASIC 122 in partially overlapping alignment with the embedded face-up photonics ICs 107, 112 in the multi-chip substrate 96, each photonic IC (e.g., 107) is in close electrical communication with a corresponding electronic IC (e.g., 121).

On the top of the face-up photonic ICs 107, 112, the first or upper RDL stack 113-115 may be selectively forming and/or etched to expose a fiber coupling region at a peripheral top side of the face-up photonic ICs 107, 112 while leaving a remnant first or upper RDL stack 113-115 for connecting the photonic ICs 107, 112 to the electrical ICs 121, 123. As a result, a ferrule 130 may be used to place an optical fiber 131 for edge coupling with the exposed fiber coupling region on top of the photonic IC 107 before using a tacking adhesive or glob top 132 to affix the optical fiber 131 to the photonic IC 107. By forming the multi-chip substrate 101-115 to include exposed fiber coupling regions on top of the photonic ICs 107, 112, optical waveguide fibers can be directly attached without requiring any overhang of the photonic ICs, without requiring any cutout or etching of the multi-chip substrate 101-115, and without requiring that the optical fiber attach materials are reflow-compatible.

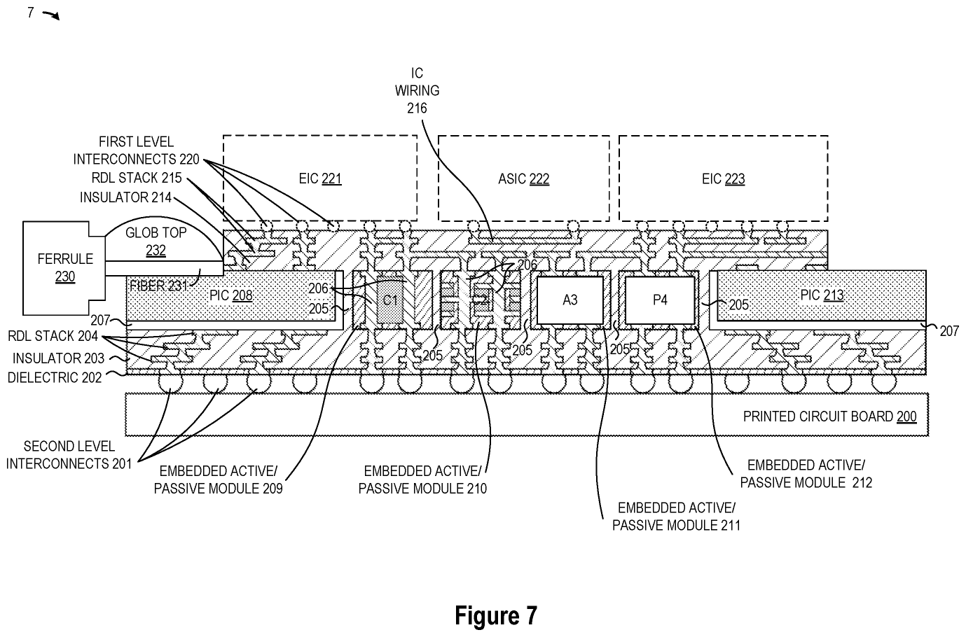

For an improved understanding of selected embodiments of the present disclosure, reference is now made to FIG. 7 which depicts a cross-sectional view of an integrated circuit package assembly 7 wherein a plurality of die/chip modules 221-223 are affixed to a multi-chip package substrate 201-216 with embedded active and/or passive modules 209-212 and face-up photonics ICs 208, 213, each of which is sitting or positioned in a blind cavity formed by a cavity layer 207. As depicted, the integrated circuit package assembly 6 is implemented as a flip chip package wherein the die/chip modules 221-223 are connected to one another and to the printed circuit board 200 using defined conductive elements and the embedded active and/or passive modules in the multi-chip package substrate 201-216. In particular, the flip chip package assembly has a plurality of surface-attachable die or module devices 221-223, including discrete electronics integrated circuits 221, 223 and an ASIC 222 which are each attached over first level interconnects 220 (e.g., solder bumps or micro-bumps) to a first or upper RDL stack 214-216. In turn, conductors in the first or upper RDL stack 214-216 provide electrical and/or thermal conductive paths to the embedded active and/or passive modules 208-213 in the multi-chip package substrate 201-216. As depicted, the embedded active and/or passive modules 208-213 may be embedded in a substrate core layer and may include one or more different circuit components, such as one or more “face-up” photonic IC dice 208, 213, an embedded vertical planar capacitor C1 at embedded module 209, an embedded sandwich multi-layer capacitor C2 at embedded module 210, an active circuit component A3 at embedded module 211, and/or a passive circuit component P4 at embedded module 212. In addition, conductors in the second or lower RDL stack 202-204 provide electrical and/or thermal conductive paths to second level interconnects 201.

On the top of the face-up photonic ICs 208, 213, the first or upper RDL stack 214-216 may be selectively forming and/or etched to expose a fiber coupling region at a peripheral top side of the face-up photonic ICs 208, 213 while leaving a remnant first or upper RDL stack 214-216 for connecting the photonic ICs 208, 213 to the electrical ICs 221, 223. As a result, a ferrule 230 may be used to place an optical fiber 231 for edge coupling with the exposed fiber coupling region on top of the photonic IC 208 before using a tacking adhesive or glob top 232 to affix the optical fiber 231 to the photonic IC 208. By forming the multi-chip substrate 201-216 to include exposed fiber coupling regions on top of the photonic ICs 208, 213, optical waveguide fibers can be directly attached without requiring any overhang of the photonic ICs, without requiring any cutout or etching of the multi-chip substrate 201-216, and without requiring that the optical fiber attach materials are reflow-compatible. And by forming the face-up photonics ICs 208, 213 in a blind cavity formed by a cavity layer 207, this enables the multi-chip substrate 201-216 to be thicker without requiring that the photonic ICs 208, 213 are also thicker. As a result, the thicker multi-chip substrate 201-216 provides more room for the ferrule 230 in the z-axis (in cases where the fiber ferrule complex is much thicker than the substrate).

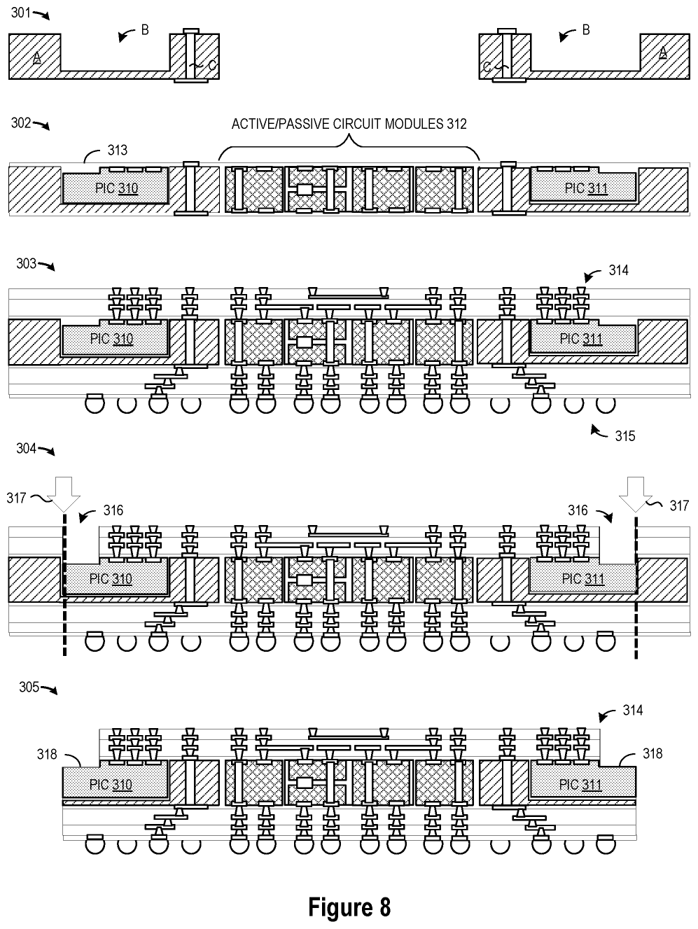

To illustrate an example sequence of process steps for fabricating an integrated circuit package assembly in accordance with selected blind cavity embodiments of the present disclosure, reference is now made to FIG. 8 which shows cross-sectional views 301-305 of example manufacturing process steps for embedding photonics integrated circuits 310, 311 in a multi-chip substrate. As illustrated, the multi-chip substrate illustrated in FIG. 8 is similar to the multi-chip substrate 201-216 depicted in FIG. 7, so the reference numbering for the constituent components and layers in the multi-chip package substrate are not repeated.

In the depicted process flow shown with cross-sectional view 301, a glass substrate A is processed to form blind cavities B and through-glass-vias (TGVs) C at predetermined locations using any suitable selective etching and/or laser drilling technique. In the TGVs, one or more metallization layers are selectively formed using any suitable deposition process to form conductive TGV structures and landing pads on opposing sides of the glass substrate.

In the depicted process flow shown with cross-sectional view 302, photonic ICs 310, 311 are embedded in the blind cavities, followed by a cavity fill and grinding process to planarize the upper surface of the glass substrate so that the photonic ICs 310, 311 are fully embedded. As depicted, each photonic IC 310, 311 may be placed as a face-up PIC with an exposed fiber coupling region located on an upper surface of the PIC where a V-groove is formed. As depicted, the photonic ICs 310, 311 are “blind” in the sense that there are electrical signal connections provided on only the upper side to the upper redistribution wiring layers 314. As part of the embedding process flow, one or more active and/or passive circuit component modules 312 may also be embedded in the glass substrate. Once the photonic ICs 310, 311 are positioned in the blind cavities, one or more dielectric layers 313 may be deposited to cover the photonic ICs 310, 311 and fill the cavities, followed by a grinding or polishing process to planarize the upper surface of the dielectric layer(s) 313.

In the depicted process flow shown with cross-sectional view 303, redistribution wiring layers 314, 315 are built up on the top and bottom surfaces of the glass substrate. As depicted, the redistribution wiring layers 314, 315 may be formed by sequentially forming and patterning insulator and conductor layers to connect the embedded photonic ICs 310, 311 and active and/or passive circuit component modules 312. As illustrated, there may be first or second level interconnects formed on the redistribution wiring layers 314, 315, such as by attaching BGA solder balls, bumps, micro-bumps, or the like.

In the depicted process flow shown with cross-sectional view 304, selective etch processing may be applied to expose the fiber coupling regions on the embedded photonic ICs 310, 311 where the V-groove is formed. While any suitable selective etch process may be used, selected embodiments may employ a patterned masking layer (not shown) that is formed over upper redistribution wiring layers 314, followed by applying a directionalized and/or localized etching process to form openings 316 which expose the fiber coupling regions on the embedded photonic ICs 310, 311. Upon removing any patterned masking layer, one or more integrated circuit chips of dice (not shown) may be attached to the upper redistribution wiring layers 314 along with an injected underfill material or layer (not shown) between the IC chips/dice and the underlying multi-chip package substrate. As indicated by directional cutting lines 317, the integrated circuit package assembly may be singulated with a saw or laser or other cutting device that is applied along defined saw cut lines or scribe grids to cut down through the multi-chip package substrate.

In the depicted process flow shown with cross-sectional view 305, the singulated multi-chip package substrate is formed to include an upper redistribution wiring layer stack 314 which covers the part of the multi-chip package substrate but which leaves exposed the side edges of the (etched) photonic ICs 310, 311 where the V-groove is formed. At this point, additional package processing steps may be applied, including board level assembly and attachment of optical fibers to the exposed fiber coupling regions on the embedded photonic ICs 310, 311.

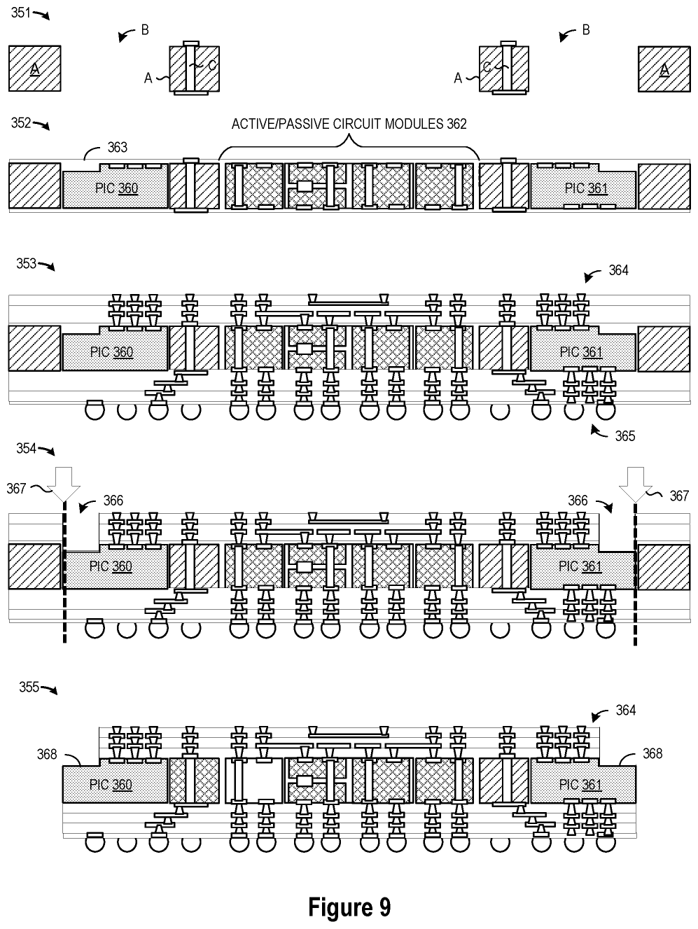

To illustrate an example sequence of process steps for fabricating an integrated circuit package assembly in accordance with selected through cavity embodiments of the present disclosure, reference is now made to FIG. 9 which shows cross-sectional views 351-355 of example manufacturing process steps for embedding photonics integrated circuits 360, 361 in a multi-chip substrate. As illustrated, the multi-chip substrate illustrated in FIG. 9 is similar to the multi-chip substrate 101-115 depicted in FIG. 6, so the reference numbering for the constituent components and layers in the multi-chip package substrate are not repeated.

In the depicted process flow shown with cross-sectional view 351, a glass substrate A is processed to form through cavities B which extend completely through the glass substrate using any suitable selective etching and/or laser drilling technique. In addition, through-glass-vias (TGVs) C are formed in the glass substrate at predetermined locations using any suitable selective etching and/or laser drilling technique. In the TGVs, one or more metallization layers are selectively formed using any suitable deposition process to form conductive TGV structures and landing pads on opposing sides of the glass substrate.

In the depicted process flow shown with cross-sectional view 352, photonic ICs 360, 361 are embedded in the through cavities formed in the substrate core (A), followed by a cavity fill and grinding process to planarize the upper surface of the glass substrate so that the photonic ICs 360, 361 are fully embedded. As depicted, each photonic IC 360, 361 may be placed as a face-up PIC with an exposed fiber coupling region located on an upper surface of the PIC where a V-groove is formed. As depicted, the photonic ICs 360, 361 are positioned to extend across the through cavities of the substrate core (A) in the sense that it is possible to have electrical signal connections made to the photonic ICs 360, 361 from both the upper and lower to the upper redistribution wiring layer stacks 364, 365 that are subsequently formed. As part of the embedding process flow, one or more active and/or passive circuit component modules 362 (cross-hatched) may also be embedded in the glass substrate core. Once the photonic ICs 360, 361 are positioned in the through cavities, one or more dielectric layers 363 may be deposited to cover the photonic ICs 360, 361 and fill the cavities, followed by a grinding or polishing process to planarize the upper surface of the dielectric layer(s) 363.

In the depicted process flow shown with cross-sectional view 353, redistribution wiring layers 364, 365 are built up on the top and bottom surfaces of the glass substrate. As depicted, the redistribution wiring layers 364, 365 may be formed by sequentially forming and patterning insulator and conductor layers to connect the embedded photonic ICs 360, 361 and active and/or passive circuit component modules 362. As illustrated, there may be first or second level interconnects formed on the redistribution wiring layers 364, 365, such as by attaching BGA solder balls, bumps, micro-bumps, or the like.

In the depicted process flow shown with cross-sectional view 354, selective etch processing may be applied to expose the fiber coupling regions on the embedded photonic ICs 360, 361 where the V-groove is formed. While any suitable selective etch process may be used, selected embodiments may employ a patterned masking layer (not shown) that is formed over upper redistribution wiring layers 364, followed by applying a directionalized and/or localized etching process to form openings 366 which expose the fiber coupling regions on the embedded photonic ICs 360, 361. Upon removing any patterned masking layer, one or more integrated circuit chips of dice (not shown) may be attached to the upper redistribution wiring layers 364 along with an injected underfill material or layer (not shown) between the IC chips/dice and the underlying multi-chip package substrate. As indicated by directional cutting lines 367, the integrated circuit package assembly may be singulated with a saw or laser or other cutting device that is applied along defined saw cut lines or scribe grids to cut down through the multi-chip package substrate.

In the depicted process flow shown with cross-sectional view 365, the singulated multi-chip package substrate is formed to include an upper redistribution wiring layer stack 364 which covers the part of the multi-chip package substrate but which leaves exposed the side edges of the (etched) photonic ICs 360, 361 where the V-groove is formed. At this point, additional package processing steps may be applied, including board level assembly and attachment of optical fibers to the exposed fiber coupling regions on the embedded photonic ICs 360, 361.

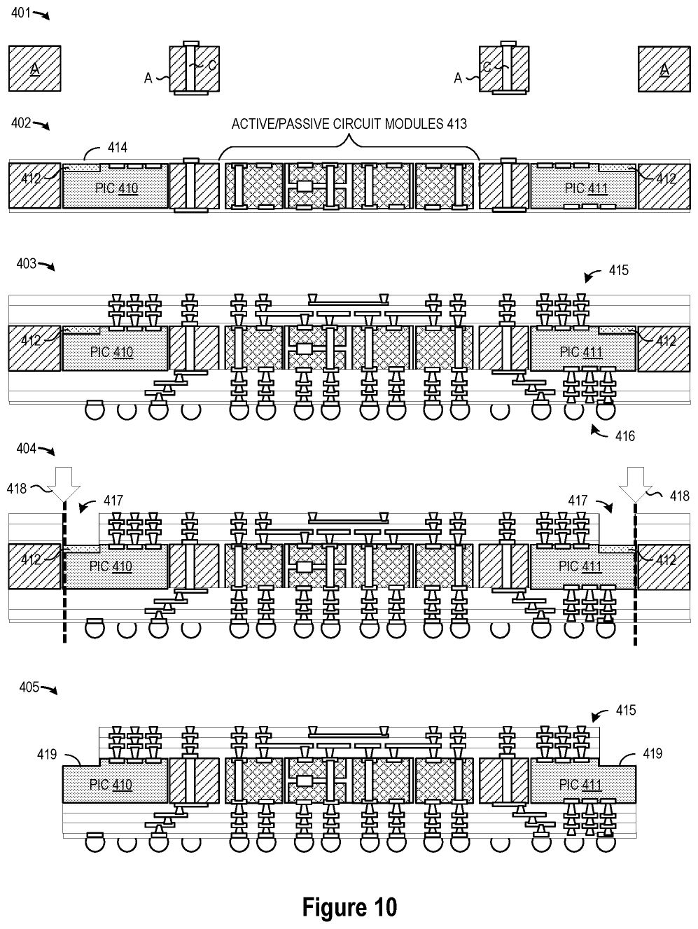

To illustrate an example sequence of process steps for fabricating an integrated circuit package assembly in accordance with selected embodiments of the present disclosure which use a sacrificial protection layer when embedding photonics integrated circuits, reference is now made to FIG. 10 which shows cross-sectional views 401-405 of example manufacturing process steps for embedding photonics integrated circuits 410, 411 in a multi-chip substrate. As illustrated, the multi-chip substrate illustrated in FIG. 10 is similar to the multi-chip substrate 101-115 depicted in FIG. 6, so the reference numbering for the constituent components and layers in the multi-chip package substrate are not repeated.

In the depicted process flow shown with cross-sectional view 401, a glass substrate core (A) is processed to form through cavities B and through-glass-vias (TGVs) C which extend through the entirety of the glass substrate at predetermined locations using any suitable selective etching and/or laser drilling technique. In the TGVs, one or more metallization layers are selectively formed using any suitable deposition process to form conductive TGV structures and landing pads on opposing sides of the glass substrate.

In the depicted process flow shown with cross-sectional view 402, photonic ICs 410, 411 are embedded in the through cavities of the substrate core (A), followed by a cavity fill and grinding process to planarize the upper surface of the glass substrate so that the photonic ICs 410, 411 are fully embedded. As depicted, each photonic IC 410, 411 may be placed as a face-up PIC with an exposed fiber coupling region located on an upper surface of the PIC where a V-groove is formed. In addition, a sacrificial protection layer 412 may be deposited or otherwise formed on an upper surface of the PIC to protect the exposed fiber coupling region from any chemical processing exposure that may be used during the subsequent fabrication process (e.g., RDL and assembly processes). As formed, the sacrificial protection layer 412 can stay in place through the embedding process and removed prior to the fiber attach step. As part of the embedding process flow, one or more active and/or passive circuit component modules 413 (cross hatched) may also be embedded in the glass substrate. Once the photonic ICs 410, 411 are positioned in the through cavities, one or more dielectric layers 414 may be deposited to cover the photonic ICs 410, 411 and fill the cavities, followed by a grinding or polishing process to planarize the upper surface of the dielectric layer(s) 414.

In the depicted process flow shown with cross-sectional view 403, redistribution wiring layers 415, 416 are built up on the top and bottom surfaces of the glass substrate. As depicted, the redistribution wiring layers 415, 416 may be formed by sequentially forming and patterning insulator and conductor layers to connect the embedded photonic ICs 410, 411 and active and/or passive circuit component modules 413. As illustrated, there may be first or second level interconnects formed on the redistribution wiring layers 415, 416, such as by attaching BGA solder balls, bumps, micro-bumps, or the like.

In the depicted process flow shown with cross-sectional view 404, selective etch processing may be applied to expose the sacrificial protection layer 412 formed over the fiber coupling regions on the embedded photonic ICs 410, 411. Any suitable selective etch process may be used that is selective to remove the redistribution wiring layer 415 without removing the sacrificial protection layer 412. For example, a patterned masking layer (not shown) may be formed over upper redistribution wiring layers 415, followed by applying a directionalized and/or localized etching process to form openings 417 which expose the sacrificial protection layer 412 formed over the fiber coupling regions on the embedded photonic ICs 410, 411. Upon removing any patterned masking layer, one or more integrated circuit chips of dice (not shown) may be attached to the upper redistribution wiring layers 415 along with an injected underfill material or layer (not shown) between the IC chips/dice and the underlying multi-chip package substrate. As indicated by directional cutting lines 418, the integrated circuit package assembly may be singulated with a saw or laser or other cutting device that is applied along defined saw cut lines or scribe grids to cut down through the multi-chip package substrate.

In the depicted process flow shown with cross-sectional view 405, the sacrificial protection layer 412 has been selectively etched or otherwise removed using any suitable process, thereby forming a singulated multi-chip package substrate which includes an upper redistribution wiring layer stack 415 which covers the part of the multi-chip package substrate but which leaves exposed the side edges of the (etched) photonic ICs 410, 411 where the V-groove is formed. At this point, additional package processing steps may be applied, including board level assembly and attachment of optical fibers to the exposed fiber coupling regions on the embedded photonic ICs 410, 411.

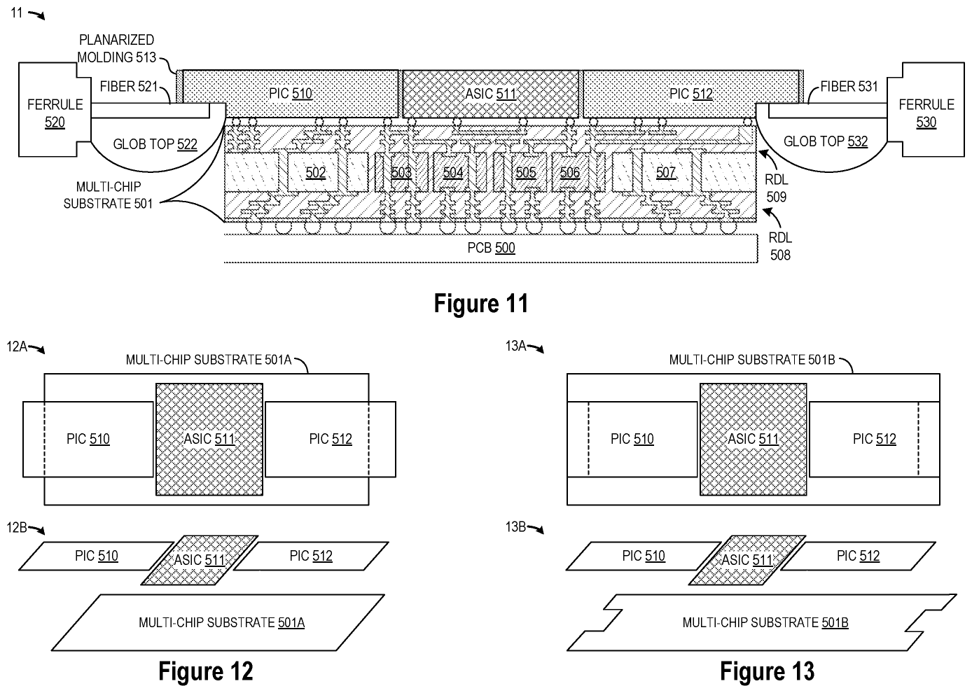

For an improved understanding of selected embodiments of the present disclosure, reference is now made to FIG. 11 which depicts a cross-sectional view of an integrated circuit package assembly 11 wherein a face down photonics integrated circuit 510, 512 and an ASIC circuit 511 are attached to a multi-chip package substrate 501 with embedded active and/or passive modules 502-507. As depicted, the integrated circuit package assembly 11 is implemented as a flip chip package wherein the die/chip modules 510-512 are connected to one another and to the printed circuit board 500 using defined conductive elements and the embedded active and/or passive modules in the multi-chip package substrate 501-509. In particular, the flip chip package assembly has a plurality of surface-attachable die or module devices 510-512, including discrete photonic integrated circuits 510, 512 and an ASIC 511 which are each attached over first level interconnects (e.g., solder bumps or micro-bumps) to a first or upper RDL stack 509. In turn, conductors in the first or upper RDL stack 509 provide electrical and/or thermal conductive paths to the embedded active and/or passive modules 502-507 in the multi-chip package substrate 501. As depicted, the embedded active and/or passive modules 502-507 may include a variety of different circuit components, such as an embedded vertical planar capacitor, an embedded sandwich multi-layer capacitor, an active circuit component, and/or a passive circuit component. In addition, conductors in the second or lower RDL stack 508 provide electrical and/or thermal conductive paths to second level interconnects (e.g., solder balls).

As depicted, the face-down photonics ICs 510, 512 and ASIC 511 each have an active area formed on a bottom surface so that the die/chips 510-512 are connected to communicate with one another over defined conductive elements in the first level interconnects and first or upper RDL stack 509. In selected embodiments, the die/chips 510-512 may be encapsulated in a planarized and/or grinded molding compound 513, but in other embodiments, the die/chips 510-512 may attached to the multi-chip package substrate 501-509 without any molding compound encapsulating the die/chips 510-512.

To promote attachment of a waveguide fiber to the active face-down surface of the photonics ICs 510, 512, the photonics ICs 510, 512 are positioned at the sides of the ASIC 511 and are attached to the multi-chip package substrate 501 to extend past the side(s) of the multi-chip package substrate 501 so that fiber coupling regions are exposed at a peripheral bottom side of the photonic ICs 510, 512. As disclosed herein, the fiber coupling regions may include V-grooves in the side edge of the photonics IC for use with aligning the edge coupling or connection of the optical fiber to the end-fire waveguide(s) on a photonics ICs 510, 512. Such an attachment is shown at the bottom of the face-down photonic ICs 510, 512 where the ferrules 520, 530 are used to place an optical fibers 521, 531 for edge coupling with the exposed fiber coupling region on bottom of the photonic ICs 510, 512 before using a tacking adhesive or glob top 522, 532 to affix the optical fibers 521, 531 to the photonic ICs 510, 512. By forming the multi-chip substrate 501-509 to expose the fiber coupling regions on bottom of the photonic ICs 510, 512, optical waveguide fibers can be directly attached without requiring that the optical fiber attach materials are reflow-compatible.

To provide a first example for forming the multi-chip substrate to expose the fiber coupling regions on bottom of the photonic ICs, reference is now made to FIG. 12 which illustrates simplified plan view 12A and perspective view 12B of a face down photonics integrated circuit which overhangs an underlying attached multi-chip substrate in accordance with selected embodiments of the present disclosure. In particular, the plan view 12A shows that the multi-chip package substrate 501A may have a rectangular shape where the side edges (indicated with dashed lines) may be positioned under the photonic ICs 510, 512, and ASIC 511 except for a protruding side edge of the photonics ICs 510, 512 which extend past the side(s) of the multi-chip package substrate 501A. This same spatial relationship between the rectangular-shaped multi-chip package substrate 501A and the protruding photonics ICs 510, 512 is depicted with the perspective view 12B.

To provide a second example for forming the multi-chip substrate to expose the fiber coupling regions on bottom of the photonic ICs, reference is now made to FIG. 13 which illustrates simplified plan view 13A and perspective view 13B of a face down photonics integrated circuit which overhangs cutout regions from an underlying attached multi-chip substrate in accordance with selected embodiments of the present disclosure. In particular, the plan view 13A shows that the multi-chip package substrate 501B may have a rectangular shape with cutout regions on opposed sides so that the photonic ICs 510, 512 are positioned to have protruding side edges which extend over the cutout regions (indicated with dashed lines) of the multi-chip package substrate 501B. This same spatial relationship between the cutout regions of the multi-chip package substrate 501B and the protruding photonics ICs 510, 512 is depicted with the perspective view 13B.

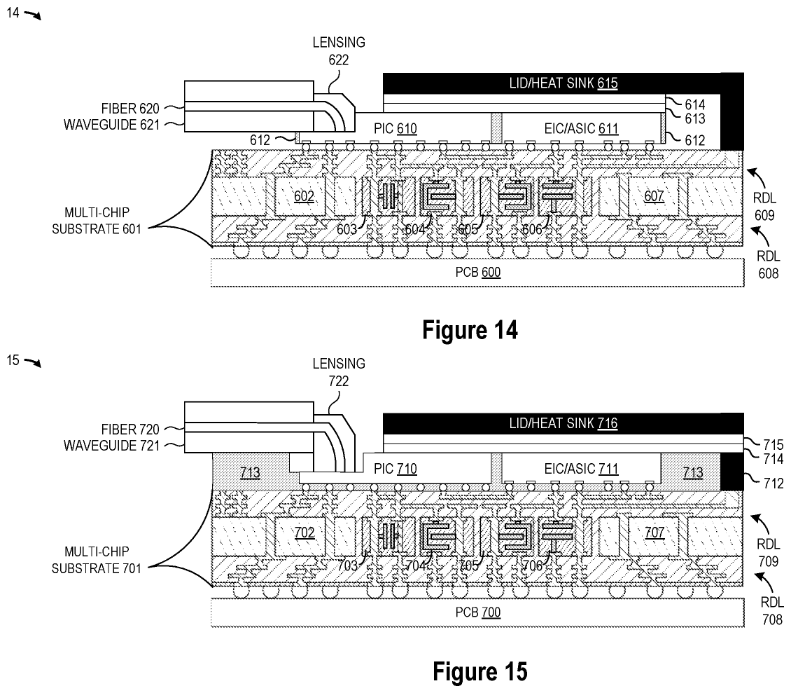

For an improved understanding of selected die-level reconstruction embodiments of the present disclosure, reference is now made to FIG. 14 which depicts a cross-sectional view of an integrated circuit package assembly 14 wherein vertical backside coupling is used with a face down photonics integrated circuit 610 and an electronic IC or ASIC circuit 611 attached to a multi-chip package substrate 601 having embedded active and/or passive modules 602-607. As depicted, the integrated circuit package assembly 14 is implemented as a flip chip package wherein the die/chip modules 610-611 are connected to one another and to the printed circuit board 600 using defined conductive elements and the embedded active and/or passive modules in the multi-chip package substrate 601-609. In particular, the flip chip package assembly has a plurality of surface-attachable die or module devices 610-611, including discrete photonic integrated circuits 610 and an EIC/ASIC 611 which are each attached over first level interconnects (e.g., solder bumps or micro-bumps) to a first or upper RDL stack 609. In turn, conductors in the first or upper RDL stack 609 provide electrical and/or thermal conductive paths to the embedded active and/or passive modules 602-607 in the multi-chip package substrate 601. As depicted, the embedded active and/or passive modules 602-607 may include a substrate core layer 602, 607 in which is embedded one or more circuit components, such as an embedded vertical planar capacitor 603, an embedded sandwich multi-layer capacitor 604, an active circuit component 605, and/or a passive circuit component 606. In addition, conductors in the second or lower RDL stack 608 provide electrical and/or thermal conductive paths to second level interconnects (e.g., solder balls).

As depicted, the face-down photonics IC 610 and EIC/ASIC 611 each have an active area formed on a bottom surface so that the die/chips 610-611 are connected to communicate with one another over defined conductive elements in the first level interconnects and first or upper RDL stack 609. The depicted die/chips 610-611 are encapsulated in a molding compound 612 which may be planarized or grinded to level the heights of the chips 610-611. In selected die-level reconstitution embodiments, a heat spreader lid or heat sink cover 615 is formed on the package assembly to make thermal contact with the die/chips 610-611. As a preliminary step, one or more backside metallization (BSM) layers 613 may be formed as patterned thermal interface material layers that are selectively formed or applied on the exposed surface(s) of the die/chips 610-611 to make direct, thermal conduction contact with the die/chips 610-611. In addition, one or more patterned thermal interface material (TIM) layers 614 may be selectively formed or applied on an exposed surface of each of the die/chips 610-611 using a compliant, thermally conductive grease or non-curing silicon material to minimize the thermal resistance between the die/chips 610-611 and the subsequently attached heat spreader lid array, and to protect the die/chips 610-611 from compression-related damage. Subsequently, a single heat spreader lid 615 is formed with thermally conductive material such as, for example, copper (e.g., CDA194 copper) or other copper alloy, nickel iron alloy (e.g., Alloy 42) or other Ni alloys, and the like. The depicted heat spreader lid 615 is placed in registry with and attached to directly thermally contact the plurality of die/chips 610-611 using the patterned TIM layer 614 and BSM layer 613 as thermally conductive layers.

After attaching the heat spreader lid/sink 615, a selective etch processing may be applied to expose the backside fiber coupling region on the top or back surface of the face-down photonic IC 610. Any suitable selective etch process may be used to etch through the heat spreader lid/sink 615 and underlying layers 613-614. For example, a patterned masking layer (not shown) may be formed over the heat spreader lid/sink 615, followed by applying one or more directionalized and/or localized etching processes to form an opening which exposes the backside fiber coupling region on the photonic ICs 610. In selected embodiments, the localized etch process(es) may include a thinning etch which is applied to the backside of the photonic IC 610 to reduce its thickness so that beam expansion effects are reduced. Upon removing any patterned masking layer, an optical waveguide fiber 620-621 and lensing structure 622 are attached to provide vertical backside coupling to the exposed backside fiber coupling region. By exposing the photonic IC 610 with a thinned or recessed backside fiber coupling region, optical waveguide fibers 620-621 can be directly attached without requiring any overhang of the photonic ICs, without requiring any cutout or etching of the multi-chip substrate 601-609, and without requiring that the optical fiber attach materials are reflow-compatible. In addition, by partially thinning the photonic IC 610 after being encapsulated in molding compound 612, the assembly process avoids problems with handling a partially thinned photonics IC that does not have structural support during assembly.

For an improved understanding of selected die-level reconstruction embodiments of the present disclosure, reference is now made to FIG. 15 which depicts a cross-sectional view of an integrated circuit package assembly 15 including a multi-chip substrate 701-709 attached to a face down photonics integrated circuit 710 and an electronic IC or ASIC circuit 711 that is connected to an optical fiber 720 using vertical backside coupling in accordance with selected substrate-level reconstruction embodiments of the present disclosure. In such substrate-level reconstitution embodiments, a plurality of multi-chip substrates is attached to a first temporary carrier before attaching multiple instances of bumped integrated circuit dice to the plurality of multi-chip substrates, and then covering the plurality of multi-chip substrates with a molding compound and heat sink lid/cover before singulation. Before or after attaching the multiple instances of bumped integrated circuit dice to the multi-chip substrates, one or more optional stiffener structures may be formed on each of the multi-chip substrates to surround or encircle the integrated circuit dice.

As depicted, the integrated circuit package assembly 15 is implemented as a flip chip package wherein the die/chip modules 710-711 are connected to one another and to the printed circuit board 700 using defined conductive elements and the embedded active and/or passive modules in the multi-chip package substrate 701-709. In particular, the surface-attachable die or module devices 710-711 include discrete face-down photonic integrated circuits 710 and an EIC/ASIC 711 which are each attached over first level interconnects (e.g., solder bumps or micro-bumps) to a first or upper RDL stack 709. In turn, conductors in the first or upper RDL stack 709 provide electrical and/or thermal conductive paths to the embedded active and/or passive modules 702-707 in the multi-chip package substrate 701 which may include a substrate core layer 702, 707 and one or more embedded components, such as an embedded vertical planar capacitor 703, an embedded sandwich multi-layer capacitor 704, an active circuit component 705, and/or a passive circuit component 706. In addition, conductors in the second or lower RDL stack 708 provide electrical and/or thermal conductive paths to second level interconnects (e.g., solder balls).

In the fabrication process, the face-down photonics IC 710 and EIC/ASIC 711 are attached to the multi-chip substrate and encapsulated in a molding compound 713 which may be planarized or grinded to level the heights of the chips 710-711. Before or after attaching the face-down photonics IC 710 and EIC/ASIC 711 to the multi-chip substrate, stiffener structures 712 can be formed on the multi-chip substrate 701 with any suitable material having structural properties that are suitable for providing mechanical support and structural integrity to reduce any warpage or bending of the multi-chip substrates 701. In addition, the material properties of the stiffener structure 712 may include thermal conductive properties to enable the stiffener structures 712 to provide a thermal conduction or heat spreading path for heat generated by the integrated circuit dice 710, 711 and/or embedded elements in the multi-chip substrate 701. As will be appreciated, the stiffener structure 712 may be formed to include a thermally conductive adhesive layer which is used to attach the stiffener structure 712 to one or more thermal conduction paths formed in the multi-chip substrate 701. For example, the thermally conductive adhesive layers may be a TIM film or tape and applied to the bottom surface of each stiffener structure 712. In selected embodiments, each stiffener structure 712 is formed as a ringed structure that surrounds the integrated circuit dice 710-711 formed in a multi-chip package substrate (e.g., 701). In other selected embodiments where the stiffener structure 712 provides a thermal conduction path for heat generated by the integrated circuit dice 710-711 and/or embedded elements in the multi-chip substrate, the height of each stiffener structure 712 is at least as tall as the shortest integrated circuit die (e.g., 710). In other embodiments where the stiffener structure 712 does not provide a thermal conduction path, the height of the stiffener structure 712 may be shorter than any of the dice. In other embodiments, the stiffener structures 712 may be omitted.

After attaching and encapsulating the integrated circuit dice 710, 711 and stiffener structure 712 with a planarized molding compound 713, a heat spreader lid or heat sink cover 716 is formed on the package assembly to make thermal contact with the die/chips 710-711. As a preliminary step, one or more backside metallization (BSM) layers 714 are formed as patterned thermal interface material layers on the exposed surface(s) of the die/chips 710-711 to make direct, thermal conduction contact with the die/chips 710-711. In addition, one or more patterned thermal interface material (TIM) layers 715 may be selectively formed or applied on an exposed surface of each of the die/chips 710-711 using a compliant, thermally conductive grease or non-curing silicon material to minimize the thermal resistance between the die/chips 710-711 and the subsequently attached heat spreader lid array 716, and to protect the die/chips 710-711 from compression-related damage. Subsequently, a single heat spreader lid 715 is formed with thermally conductive material.

After attaching the heat spreader lid/sink 716, a selective etch processing may be applied to expose the backside fiber coupling region on the top or back surface of the face-down photonic IC 710. Any suitable selective etch process may be used to etch through the heat spreader lid/sink 716 and underlying layers 714-715. For example, a patterned masking layer (not shown) may be formed over the heat spreader lid/sink 716, followed by applying one or more directionalized and/or localized etching processes to form an opening which exposes the backside fiber coupling region on the photonic ICs 710. In selected embodiments, the localized etch process(es) may include a thinning etch which is applied to the backside of the photonic IC 710 to reduce its thickness so that beam expansion effects are reduced. Upon removing any patterned masking layer, an optical waveguide fiber 720-721 and lensing structure 722 are attached to provide vertical backside coupling to the exposed backside fiber coupling region. By exposing the photonic IC 710 with a thinned or recessed backside fiber coupling region, optical waveguide fibers 720-721 can be directly attached without requiring any overhang of the photonic ICs, without requiring any cutout or etching of the multi-chip substrate 701-709, and without requiring that the optical fiber attach materials are reflow-compatible. In addition, by partially thinning the photonic IC 710 after being encapsulated in molding compound 713, the assembly process avoids problems with handling a partially thinned photonics IC that does not have structural support during assembly.

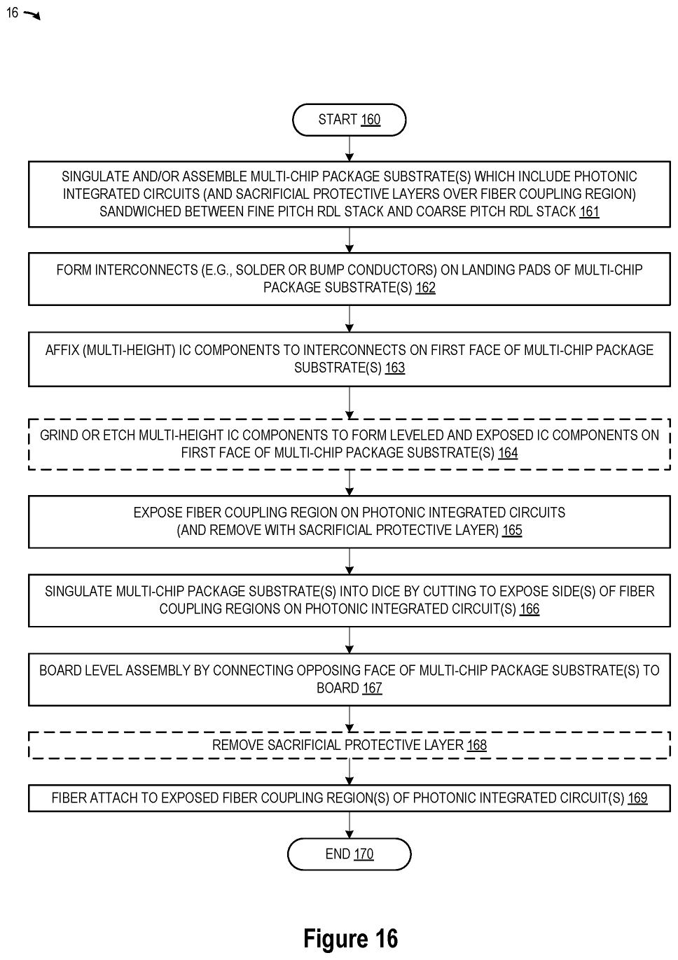

Turning now to FIG. 16, there is illustrated a simplified flow chart 16 showing an example sequence of steps 160-170 for fabricating an integrated circuit package assembly wherein an embedded photonics integrated circuit dice is co-packaged with a multi-chip package substrate. After the process begins (at step 160), one or more multi-chip package substrates are singulated and/or assembled (step 161), where each multi-chip package substrate includes at least an embedded face-up photonic integrated circuit that is sandwiched between a fine pitch RDL stack and a coarse pitch RDL stack. As indicated parenthetically at step 161, each embedded photonic integrated circuit includes a fiber coupling region that may be located on an active surface of the embedded photonic integrated circuit, and the fiber coupling region may optionally be covered by one or more sacrificial protective layers.

At step 162, interconnects are formed on the landing pads of the multi-chip package substrate. For example, interconnect conductor elements (e.g., micro-bumps) may optionally be formed on the contact terminal(s) (e.g., landing pads) of the multi-chip package substrate. In selected embodiments, the interconnect conductor elements may be built on the multi-chip package substrate to make electrical contact with exposed contact terminals therein, such as by sequentially depositing, patterning, etching insulating layers and conductive layers (e.g., plated copper) to form fine pitched plated conductor lines.

At step 163, one or more integrated circuit components are affixed to the interconnects on a first face of the multi-chip package substrate. Although any suitable method may be used to position the integrated circuit component(s), in one embodiment, a pick-and-place machine is used in positioning the integrated circuit components for attachment to the multi-chip package substrate. As indicated parenthetically at step 163, the IC components may have multiple different heights, resulting in some IC components extending further above the multi-chip package substrate than others.

At step 164, a grinding or etching process may optionally be applied to any multi-height IC components in order to level and expose the IC components on the first face of the multi-chip package substrate. In selected embodiments, the grinding or etching process may use a laser ablation process that is applied to a molding compound formed over the multi-height IC components, thereby forming a thinned encapsulated IC component panel. For example, by back-grinding the top of the molding compound to thin the encapsulated I component panel to a desired thickness that is at least as tall as the shortest integrated circuit component, the multi-height IC components (and any stiffener elements) are etched or grinded to a uniform height and are exposed at the top of the etched molding compound. As indicated by the dashed lines, step 164 is optionally applied when there are multi-height IC components.

At step 165, the fiber coupling region on the embedded photonic integrated circuit is exposed, such as by applying a selective etch process to the multi-chip package substrate. While any suitable selective etch process may be used, selected embodiments may employ a patterned masking layer that is formed over the multi-chip package substrate, followed by applying one or more directionalized and/or localized etching processes to form openings in the multi-chip package substrate which expose the fiber coupling regions on the embedded photonic ICs. As indicated parenthetically at step 165, the sacrificial protective layer may be removed to expose the fiber coupling region on the photonic integrated circuit.

At step 166, the multi-chip package substrate may be singulated into dice by cutting through the multi-chip package substrate to expose the sides of the fiber coupling regions on the photonic integrated circuits. For example, the multi-chip package substrate may be singulated with a saw or laser or other cutting device that is applied along defined saw cut lines or scribe grids to cut down through the multi-chip package substrate and thereby expose the sides of the fiber coupling regions.

At step 167, one or more board level assembly steps are performed to connect the opposing face of the multi-chip package substrate to a printed circuit board.

At step 168, any sacrificial protective layer formed on the fiber coupling region may be removed. By maintaining the sacrificial protection layer in place through the fabrication process, the underlying fiber coupling regions are protected from chemical processing effects in the fabrication process. As will be appreciated, any suitable selective etch process may be used to remove the sacrificial protective layer without damaging the rest of the multi-chip package substrate. As indicated by the dashed lines, step 168 is optionally applied when there was a sacrificial protective layer formed earlier in the fabrication process.

By now it should be appreciated that there is provided herein a method and apparatus for making an integrated circuit package assembly. As disclosed, the integrated circuit package assembly includes a multichip package substrate having active and/or passive circuit devices embedded in one or more substrate core layers. In addition, the integrated circuit package assembly includes an encapsulated plurality of integrated circuit devices attached to the multichip package substrate. The integrated circuit package assembly also includes an optical waveguide fiber connected to a photonic integrated circuit device that is located in either the multichip package substrate or the encapsulated plurality of integrated circuit devices, where the optical waveguide fiber is optically coupled to an exposed fiber coupling region of the photonic integrated circuit device. In selected embodiments, the integrated circuit package assembly also includes a heat spreader lid that is formed on and thermally connected to the encapsulated plurality of integrated circuit devices with one or more thermal conductive layers to remove heat from the encapsulated plurality of integrated circuit devices. In selected embodiments, the photonic integrated circuit device is embedded as a face-up photonic integrated circuit device in a cavity of the multichip package substrate with the exposed fiber coupling region positioned for edge coupling attachment to the optical waveguide fiber. In other selected embodiments, the photonic integrated circuit device is embedded as a face-up photonic integrated circuit device in a blind cavity of the multichip package substrate with the exposed fiber coupling region positioned for edge coupling attachment to the optical waveguide fiber. In other selected embodiments, the photonic integrated circuit device is attached as a face-down photonic integrated circuit device in the encapsulated plurality of integrated circuit devices, where the face-down photonic integrated circuit device extends laterally past a side of the multichip package substrate so that the exposed fiber coupling region is positioned for edge coupling attachment to the optical waveguide fiber. In other selected embodiments, the photonic integrated circuit device is attached as a face-down photonic integrated circuit device in the encapsulated plurality of integrated circuit devices, where the face-down photonic integrated circuit device extends laterally past a cutout region in the multichip package substrate so that the exposed fiber coupling region is positioned for edge coupling attachment to the optical waveguide fiber. In other selected embodiments, the photonic integrated circuit device is attached as a face-down photonic integrated circuit device in the encapsulated plurality of integrated circuit devices, where the face-down photonic integrated circuit device has a partially thinned backside surface forming the exposed fiber coupling region that is positioned for vertical backside coupling attachment to the optical waveguide fiber.

In another form, there is provided an integrated circuit package assembly and associated method of manufacture. The disclosed method includes assembling a multichip package substrate which includes a photonic integrated circuit device sandwiched between a first redistribution line stack and a second redistribution line stack, where the photonic integrated circuit device includes a fiber coupling region positioned at a peripheral side of the multichip package substrate and covered by the first redistribution line stack. In selected embodiments, assembling the multichip package substrate includes embedding the photonic integrated circuit device as a face-up photonic integrated circuit device with a plurality of active and/or passive circuit components in the multichip package substrate to be sandwiched between the first redistribution line stack and the second redistribution line stack. In other embodiments, assembling the multichip package substrate includes embedding the photonic integrated circuit device in a substrate core cavity of the multichip package substrate. In other embodiments, assembling the multichip package substrate includes placing the photonic integrated circuit device in a blind substrate core cavity of the multichip package substrate. In addition, the disclosed method includes selectively etching the first redistribution line stack to expose the fiber coupling region. The disclosed method also includes attaching, to the multichip package substrate, a first plurality of surface-attachable devices which have interconnect surfaces facing the multichip package substrate and which do not cover the exposed fiber coupling region of the photonic integrated circuit device, where at least one of the first plurality of surface-attachable devices comprises an electronics integrated circuit device which is positioned over and connected for communication with the photonic integrated circuit device. In selected embodiments, a sacrificial protective layer is placed over the fiber coupling region of the face-up embedded photonics integrated circuit device during assembly of the multichip package substrate (e.g., during embedding of the photonics integrated circuit device in the multichip package substrate), and subsequently, the sacrificial protective layer is removed from the fiber coupling region prior to attaching the optical waveguide fiber. In other selected embodiments, the face-up embedded photonics integrated circuit device is connected to one or both of the first redistribution line stack and second redistribution line stack. The disclosed method also includes cutting through the multichip package substrate to expose a side edge of the photonic integrated circuit device and the exposed fiber coupling region. In addition, the disclosed method includes attaching the second redistribution line stack of the multichip package substrate to a circuit board, and then attaching an optical waveguide fiber to the exposed fiber coupling region of the photonic integrated circuit device.

In yet another form, there is provided an integrated circuit package assembly and associated method of manufacture. The disclosed method includes assembling a multichip package substrate which includes a plurality of active and/or passive circuit components sandwiched between a first redistribution line stack and a second redistribution line stack. The disclosed method also includes attaching, to the first redistribution line stack of the multichip package substrate, a first plurality of surface-attachable devices which have interconnect surfaces facing the multichip package substrate, where at least one of the first plurality of surface-attachable devices comprises a photonic integrated circuit device comprising a fiber coupling region positioned to extend laterally past a side edge of the multichip package substrate. In addition, the disclosed method includes attaching the second redistribution line stack of the multichip package substrate to a circuit board, and then attaching an optical waveguide fiber to the exposed fiber coupling region of the photonic integrated circuit device. In selected embodiments, the photonic integrated circuit device is attached as a face-down photonic integrated circuit device with the fiber coupling region facing the multichip package substrate for attachment to the optical waveguide fiber. In other selected embodiments, the first plurality of surface-attachable devices are attached to the multichip package substrate as an encapsulated plurality of surface-attachable devices.

In still yet another form, there is provided an integrated circuit package assembly and associated method of manufacture. The disclosed method includes assembling a multichip package substrate which includes a plurality of active and/or passive circuit components sandwiched between a first redistribution line stack and a second redistribution line stack. The disclosed method also includes attaching, to the first redistribution line stack of the multichip package substrate, a first plurality of surface-attachable devices which have interconnect surfaces facing the multichip package substrate, where at least one of the first plurality of surface-attachable devices comprises a photonic integrated circuit device comprising a fiber coupling region positioned at a peripheral side of the first plurality of surface-attachable devices. In addition, the disclosed method includes encapsulating the first plurality of surface-attachable devices at the multichip package substrate with a molding compound structure. In selected embodiments, encapsulating the first plurality of surface-attachable devices includes attaching, to the multichip package substrate, a stiffener ring surrounding the first plurality of surface-attachable devices; encapsulating the first plurality of surface-attachable devices and the stiffener ring with a molding compound material; and curing the molding compound material to form the molding compound structure. The disclosed method also includes grinding or etching a portion of the molding compound structure and a backside surface of the photonic integrated circuit device to form a thinned backside surface in alignment with the fiber coupling region. In addition, the disclosed method includes attaching an optical waveguide fiber to the thinned backside surface of the photonic integrated circuit device. In selected embodiments, the photonic integrated circuit device is attached as a face-down photonic integrated circuit device with an active photonic integrated circuit device side facing the multichip package substrate for vertical backside coupling to the optical waveguide fiber.

Various illustrative embodiments of the present invention have been described in detail with reference to the accompanying figures. While various details are set forth in the foregoing description, it will be appreciated that the present invention may be practiced without these specific details, and that numerous implementation-specific decisions may be made to the invention described herein to achieve the device designer's specific goals, such as compliance with process technology or design-related constraints, which will vary from one implementation to another. While such a development effort might be complex and time-consuming, it would nevertheless be a routine undertaking for those of ordinary skill in the art having the benefit of this disclosure. For example, selected aspects are depicted with reference to simplified cross-sectional drawings and flow charts illustrating process and structural details of a package assembly and associated fabrication process without including every device feature or aspect in order to avoid limiting or obscuring the present invention. Such descriptions and representations are used by those skilled in the art to describe and convey the substance of their work to others skilled in the art, and the omitted details which are well known are not considered necessary to teach one skilled in the art of how to make or use the present invention. In addition, certain elements in the figures are illustrated for simplicity and clarity and have not necessarily been drawn to scale. It is also noted that, throughout this detailed description, certain layers of materials will be deposited, removed and otherwise processed to form the depicted integrated circuit die and associated packaging structures. Where the specific procedures for forming such layers are not detailed below, conventional techniques to one skilled in the art for depositing, removing or otherwise forming such layers at appropriate thicknesses shall be intended. Such details are well known and not considered necessary to teach one skilled in the art of how to make or use the present invention.

Although the described exemplary embodiments disclosed herein are directed to various packaging assemblies and methods for making same, the present invention is not necessarily limited to the example embodiments which illustrate inventive aspects of the present invention that are applicable to a wide variety of packaging processes and/or devices. Thus, the particular embodiments disclosed above are illustrative only and should not be taken as limitations upon the present invention, as the invention may be modified and practiced in different but equivalent manners apparent to those skilled in the art having the benefit of the teachings herein. For example, the multi-chip package substrates are described with reference to embedded passive components, such as capacitors, resistors, inductors, diodes, and other passive devices, but active devices may also be included as embedded components when forming the multi-chip package substrates, so these are merely exemplary circuits presented to provide a useful reference in discussing various aspects of the invention, and is not intended to be limiting so that persons of skill in the art will understand that the principles taught herein apply to other types of devices. In addition, the process steps may be performed in an alternative order than what is presented. Also, the figures do not show all the details of connections between various elements of the package, since it will be appreciated the leads, vias, bonds, circuit traces, and other connection means can be used to effect any electrical connection. Accordingly, the foregoing description is not intended to limit the invention to the particular form set forth, but on the contrary, is intended to cover such alternatives, modifications and equivalents as may be included within the spirit and scope of the invention as defined by the appended claims so that those skilled in the art should understand that they can make various changes, substitutions and alterations without departing from the spirit and scope of the invention in its broadest form.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. In addition, the term “coupled,” as used herein, is not intended to be limited to a direct coupling or a mechanical coupling. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements.

What is claimed is:

1. An integrated circuit package assembly, comprising:
a multichip package substrate comprising active and/or passive circuit devices embedded in one or more substrate core layers;
a plurality of integrated circuit devices attached to the multichip package substrate; and
an optical waveguide fiber connected to a photonic integrated circuit device that is located in either the multichip package substrate or the plurality of integrated circuit devices, where the optical waveguide fiber is optically coupled to an exposed fiber coupling region of the photonic integrated circuit device.

2. The integrated circuit package of claim 1, further comprising a heat spreader lid that is formed on and thermally connected to the plurality of integrated circuit devices with one or more thermal conductive layers to remove heat from the plurality of integrated circuit devices.

3. The integrated circuit package of claim 1, where the photonic integrated circuit device is embedded as a face-up photonic integrated circuit device in a cavity of the multichip package substrate with the exposed fiber coupling region positioned for edge coupling attachment to the optical waveguide fiber.

4. The integrated circuit package of claim 1, where the photonic integrated circuit device is embedded as a face-up photonic integrated circuit device in a blind cavity of the multichip package substrate with the exposed fiber coupling region positioned for edge coupling attachment to the optical waveguide fiber.

5. The integrated circuit package of claim 1, where the photonic integrated circuit device is attached as a face-down photonic integrated circuit device in the plurality of integrated circuit devices, where the face-down photonic integrated circuit device extends laterally past a side of the multichip package substrate so that the exposed fiber coupling region is positioned for edge coupling attachment to the optical waveguide fiber.

6. The integrated circuit package of claim 1, where the photonic integrated circuit device is attached as a face-down photonic integrated circuit device in the plurality of integrated circuit devices, where the face-down photonic integrated circuit device extends laterally past a cutout region in multichip package substrate so that the exposed fiber coupling region is positioned for edge coupling attachment to the optical waveguide fiber.

7. The integrated circuit package of claim 1, where the photonic integrated circuit device is attached as a face-down photonic integrated circuit device in the plurality of integrated circuit devices, where the face-down photonic integrated circuit device has a partially thinned backside surface forming the exposed fiber coupling region that is positioned for vertical backside coupling attachment to the optical waveguide fiber.

8. The integrated circuit package of claim 1, where the plurality of integrated circuit devices comprises an encapsulated plurality of integrated circuit devices attached to the multichip package substrate.

9. A method for making a package assembly, comprising:
assembling a multichip package substrate comprising a photonic integrated circuit device sandwiched between a first redistribution line stack and a second redistribution line stack, where the photonic integrated circuit device comprises a fiber coupling region positioned at a peripheral side of the multichip package substrate and covered by the first redistribution line stack;
selectively etching the first redistribution line stack to expose the fiber coupling region;
attaching, to the multichip package substrate, a first plurality of surface-attachable devices which have interconnect surfaces facing the multichip package substrate and which do not cover the exposed fiber coupling region of the photonic integrated circuit device, where at least one of the first plurality of surface-attachable devices comprises an electronics integrated circuit device which is positioned over and connected for communication with the photonic integrated circuit device;
cutting through the multichip package substrate to expose a side edge of the photonic integrated circuit device and the exposed fiber coupling region;
attaching the second redistribution line stack of the multichip package substrate to a circuit board; and
attaching an optical waveguide fiber to the exposed fiber coupling region of the photonic integrated circuit device.

10. The method of claim 9, where assembling the multichip package substrate comprises embedding the photonic integrated circuit device as a face-up photonic integrated circuit device with a plurality of active and/or passive circuit components in the multichip package substrate to be sandwiched between the first redistribution line stack and the second redistribution line stack.

11. The method of claim 9, where assembling the multichip package substrate comprises embedding the photonic integrated circuit device in a substrate core cavity of the multichip package substrate.

12. The method of claim 9, where assembling the multichip package substrate comprises placing the photonic integrated circuit device in a blind substrate core cavity of the multichip package substrate.

13. The method of claim 10, further comprising:
placing a sacrificial protective layer over the fiber coupling region of the face-up embedded photonics integrated circuit device during assembly of the multichip package substrate, and
removing the sacrificial protective layer from the fiber coupling region prior to attaching the optical waveguide fiber.

14. The method of claim 10, where the face-up embedded photonics integrated circuit device is connected to one or both of the first redistribution line stack and second redistribution line stack.

15. A method for making a package assembly, comprising:
assembling a multichip package substrate comprising a plurality of active and/or passive circuit components sandwiched between a first redistribution line stack and a second redistribution line stack;
attaching, to the first redistribution line stack of the multichip package substrate, a first plurality of surface-attachable devices which have interconnect surfaces facing the multichip package substrate, where at least one of the first plurality of surface-attachable devices comprises a photonic integrated circuit device comprising a fiber coupling region positioned to extend laterally past a side edge of the multichip package substrate;
attaching the second redistribution line stack of the multichip package substrate to a circuit board; and
attaching an optical waveguide fiber to the exposed fiber coupling region of the photonic integrated circuit device.

16. The method of claim 15, where the photonic integrated circuit device is attached as a face-down photonic integrated circuit device with the fiber coupling region facing the multichip package substrate for attachment to the optical waveguide fiber.

17. The method of claim 15, where the first plurality of surface-attachable devices are attached to the multichip package substrate as an encapsulated plurality of surface-attachable devices.

18. A method for making a package assembly, comprising:
assembling a multichip package substrate comprising a plurality of active and/or passive circuit components sandwiched between a first redistribution line stack and a second redistribution line stack;
attaching, to the first redistribution line stack of the multichip package substrate, a first plurality of surface-attachable devices which have interconnect surfaces facing the multichip package substrate, where at least one of the first plurality of surface-attachable devices comprises a photonic integrated circuit device comprising a fiber coupling region positioned at a peripheral side of the first plurality of surface-attachable devices;
encapsulating the first plurality of surface-attachable devices at the multichip package substrate with a molding compound structure;
grinding or etching a portion of the molding compound structure and a backside surface of the photonic integrated circuit device to form a thinned backside surface in alignment with the fiber coupling region; and
attaching an optical waveguide fiber to the thinned backside surface of the photonic integrated circuit device.

19. The method of claim 18, where the photonic integrated circuit device is attached as a face-down photonic integrated circuit device with an active photonic integrated circuit device side facing multichip package substrate for vertical backside coupling to the optical waveguide fiber.

20. The method of claim 18, where encapsulating the first plurality of surface-attachable devices with the molding compound structure comprises:
attaching, to the multichip package substrate, a stiffener ring surrounding the first plurality of surface-attachable devices;
encapsulating the first plurality of surface-attachable devices and the stiffener ring with a molding compound material; and
curing the molding compound material to form the molding compound structure.
